(19) United States
(12) Patent Application Publication
(10) Pub. No.: US 2011/0076421 A1
(43) Pub. Date: Mar. 31, 2011

(54) VAPOR DEPOSITION REACTOR FOR FORMING THIN FILM ON CURVED SURFACE

(75) Inventor: Sang In LEE, Sunnyvale, CA (US)

(73) Assignee: SYNOS TECHNOLOGY, INC., Sunnyvale, CA (US)

(21) Appl. No.: 12/890,504

(22) Filed: Sep. 24, 2010

Related U.S. Application Data
(60) Provisional application No. 61/247,096, filed on Sep. 30, 2009.
(60) Provisional application No. 61/366,906, filed on Jul. 22, 2010.

(51) Int. Cl. C23C 16/50; C23C 16/458; C23C 16/44; C23C 16/455; C23C 16/00

(52) U.S. Cl. 427/569; 118/719; 427/255.23; 427/255.28

(57) ABSTRACT

A vapor deposition reactor and a method for forming a thin film. The vapor deposition reactor includes first to third portions arranged along an arc of a circle. The first portion includes at least one first injection portion for injecting a material to a recess in the first portion. The second portion is adjacent to the first portion and has a recess communicatively connected to the recess of the first portion. The third portion is adjacent to the second portion and has a recess communicatively connected to the recess of the second portion and an exhaust portion for discharging the material from the vapor deposition reactor.

### CROSS-REFERENCE TO RELATED APPLICATION

This application claims priority from and the benefit under 35 U.S.C. §119(e) of U.S. Patent Application No. 61/247,096, entitled “Depositing Thin Films on Curved or Flexible Substrate,” filed on Sep. 30, 2009, and U.S. Patent Application No. 61/366,906, entitled “Remote Plasma Assisted Atomic Layer Deposition,” filed on Jul. 22, 2010, which are incorporated by reference herein in their entirety.

### BACKGROUND

1. Field of the Invention

This disclosure relates to a vapor deposition reactor and a method for forming a thin film on a curved surface.

2. Description of Related Art

An atomic layer deposition (ALD) process includes four stages: (i) injection of a source precursor, (ii) removal of a physical adsorption layer, (iii) injection of a reactant precursor, and (iv) removal of a physical adsorption layer. For example, U.S. Patent Application Publication No. 2009/0165715, which is incorporated herein by reference in its entirety, describes a vapor deposition reactor with a unit module (so-called a linear injector) capable of forming an atomic layer. The unit module includes an injection unit and an exhaust unit for a source material (a source module), and an injection unit and an exhaust unit for a reactant (a reactant module). The source module and the reactant module are disposed adjacent to each other.

FIG. 1 illustrates a conventional ALD vapor deposition chamber 1000 having two sets of linear reactors 1100, 1200 for depositing ALD layers on flat substrates. In a first linear reactor 1100, the flat substrates 1300 pass below a source module and a purge/pumping unit. The source module includes a source precursor injection unit that injects a source precursor in gas phase onto the flat substrates 1300. The purge/pumping unit leaves behind chemisorbed source precursor molecules on flat substrates 1300 but removes physisorbed source precursor molecules from the flat substrates 1300.

The flat substrates 1300 then pass below a second linear injector 1200 which includes a reactant module having a reactant precursor injection unit and a purge/pumping unit. The reactant precursor injection unit injects a reactant precursor in gas phase onto the flat substrates 1300. The purge/pumping unit of the reactant module removes physisorbed reactant precursor molecules to obtain an ALD layer. Leaked or diffused source precursor gas does not mix with the reactant precursor gas inside the reactor because the source module is spatially separated with the reactant module and the chamber 1000 is exhausted by a pumping system.

### SUMMARY OF THE INVENTION

Embodiments provide a vapor deposition reactor and a method for forming a thin film on a curved surface, such as an interior wall of a tube, an exterior wall of a tube, a front-side of a flexible substrate, a back-side of a flexible substrate, or both sides of a flexible substrate. To deposit atomic layer deposition (ALD) films on a curved substrate, vapor deposition reactors continuously supply reaction materials such as a source precursor and a reactant precursor onto a non-planar surface. Further, an inert gas such as Ar gas is supplied to detach excess source precursor molecules and/or reactant precursor molecules from the curved surface. The remaining source precursor, reactant precursor and Ar gas may be exhausted from the vapor deposition reactor using a pump.

In one embodiment, the vapor deposition reactor includes: a first portion formed with a first recess communicatively connected to at least one first injection portion for injecting a first material into the first recess; a second portion adjacent to the first portion, the second portion formed with a second recess communicatively connected to the first recess; and a third portion adjacent to the second portion. The third portion is formed with a third recess communicatively connected to the second recess and an exhaust portion for discharging the first material from the vapor deposition reactor. The first portion, the second portion and the third portion are arranged along an arc of a circle.

In one embodiment, the method for forming a thin film on a curved surface includes: providing a vapor deposition reactor comprising a first portion, a second portion and a third portion arranged along an arc of a circle; filling a first material in a first recess formed in the first portion by providing the first material via at least one first injection portion; receiving the first material in a second recess formed in the second portion via the first recess, the second portion located adjacent to the first portion; receiving the first material in a third recess formed in the third portion via the second recess, the third portion located adjacent to the second portion; discharging the first material in the third recess via an exhaust portion formed in the third portion; and moving the curved surface across the first recess, the second recess and the third recess.

### BRIEF DESCRIPTION OF THE DRAWINGS

The above and other aspects, features and advantages of the present invention will become apparent from the following description of preferred embodiments given in conjunction with the accompanying drawings, in which:

FIG. 1 is a perspective view of a conventional atomic layer deposition (ALD) vapor deposition chamber.

FIG. 2A is a sectional view of a vapor deposition reactor according to an embodiment.

FIG. 2B is a perspective view of the vapor deposition reactor of FIG. 2A.

FIG. 3 is an exploded perspective view of the vapor deposition reactor according to the embodiment.

FIGS. 4 to 6 are sectional views of the vapor deposition reactor according to the embodiment.

FIG. 7 is a cross-sectional view of a vapor deposition reactor obtained by adding a plasma unit to the vapor deposition reactor of FIGS. 2 to 6.

FIG. 8 is a cross-sectional view of a vapor deposition reactor according to another embodiment.

FIG. 9 is a cross-sectional view of a vapor deposition reactor obtained by adding a plasma unit to the vapor deposition reactor of FIG. 8.

FIG. 10 is a cross-sectional view of a vapor deposition reactor according to still another embodiment.

FIG. 11 is a cross-sectional view of a vapor deposition reactor obtained by adding a plasma unit to the vapor deposition reactor of FIG. 10.

FIGS. 12 to 14 are cross-sectional views of vapor deposition reactors according to still other embodiments.

FIG. 15 is a cross-sectional view of a vapor deposition reactor according to still another embodiment.

FIG. 16 is a cross-sectional view of a vapor deposition reactor obtained by adding a plasma unit to the vapor deposition reactor of FIG. 15.

FIG. 17 is a cross-sectional view of a vapor deposition reactor according to still another embodiment.

FIG. 18 is a cross-sectional view of a vapor deposition reactor according to still another embodiment.

FIG. 19 is a cross-sectional view of a vapor deposition reactor according to still another embodiment.

FIG. 20 is a cross-sectional view of a vapor deposition reactor obtained by adding a plasma unit to the vapor deposition reactor of FIG. 19.

FIG. 21 is a cross-sectional view of a vapor deposition reactor according to still another embodiment.

FIG. 22 is a cross-sectional view of a vapor deposition reactor obtained by adding a plasma unit to the vapor deposition reactor of FIG. 21.

FIG. 23 is a cross-sectional view of a vapor deposition reactor according to still another embodiment.

FIG. 24A is an exploded perspective view of a vapor deposition reactor according to an embodiment.

FIG. 24B is a longitudinal deposition reactor illustrated in FIG. 24.

FIGS. 25 and 26 are schematic views of deposition apparatuses including a vapor deposition reactor according to the embodiments.

### DETAILED DESCRIPTION OF THE INVENTION

Exemplary embodiments now will be described more fully hereinafter with reference to the accompanying drawings, in which exemplary embodiments are shown. This disclosure may, however, be embodied in many different forms and should not be construed as limited to the exemplary embodiments set forth therein. Rather, these example embodiments are provided so that this disclosure will be thorough and complete, and will fully convey the scope of this disclosure to those skilled in the art. In the description, details of well-known features and techniques may be omitted to avoid unnecessarily obscuring the presented embodiments.

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements. The shape, size and regions, and the like, of the drawing may be exaggerated for clarity.

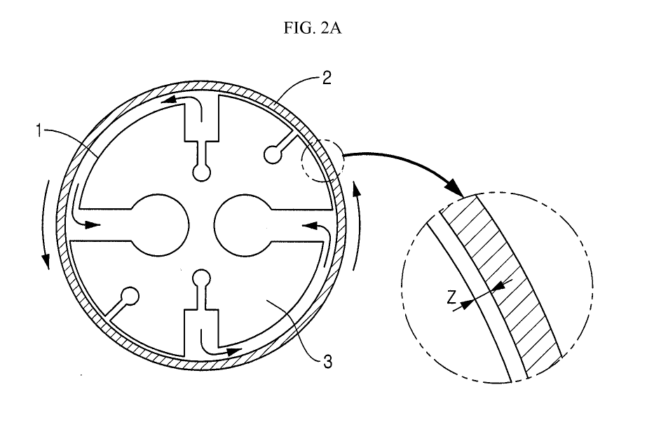

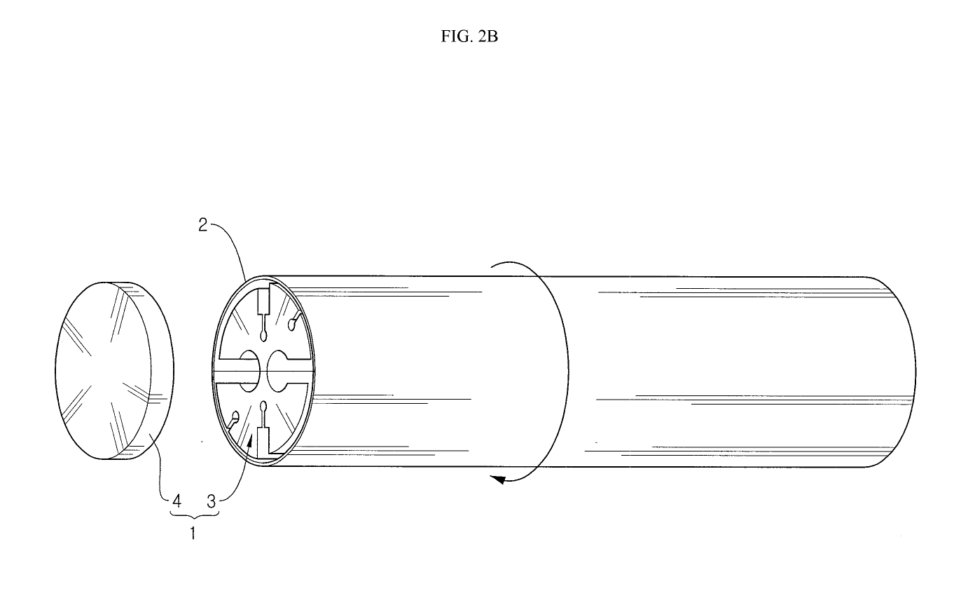

FIG. 2A is a sectional view of a vapor deposition reactor according to an embodiment. FIG. 2B is a perspective view of the vapor deposition reactor of FIG. 2A. Vapor deposition reactor 1 may at least partially have the shape of a cylinder. The vapor deposition reactor 1 may be inserted into a tube 2 in which a thin film is to be deposited. The vapor deposition reactor 1 may include a body 3 having an injection portion and an exhaust portion, formed therein. Here, the injection portion injects a reactant for forming a thin film, and the like, and the exhaust portion exhausts extra reactant and the like from the vapor deposition reactor 1. The vapor deposition reactor 1 may further include a cover 4 that covers the body 3.

The vapor deposition reactor 1 is relatively moved with respect to the tube 2, so that a reactant injected by the vapor deposition reactor 1 is deposited on the inner surface of the tube 2 to form a thin film on the inner surface of the tube 2. For example, the vapor deposition reactor 1 may be rotated with the tube 2 fixed. Alternatively, the tube 2 may be rotated with the vapor deposition reactor 1 fixed. The gap between the vapor deposition reactor 1 and the inner surface of the tube 2 may be different at different locations of the circumference. In the section identified by a dashed circle in FIG. 2A, the gap between an outer circumferential portion of the vapor deposition reactor 1 and the inner surface of the tube 2 may be z. For example, the interval z may be about 0.1 to 3 mm.

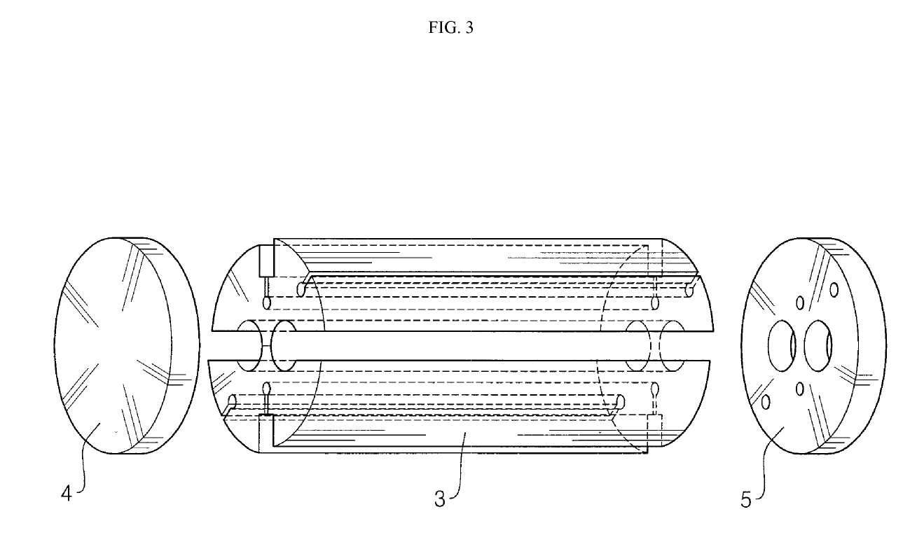

FIG. 3 is an exploded perspective view of the vapor deposition reactor of FIG. 2A. The vapor deposition reactor may include a body 3 having an injection portion, an exhaust portion and the like, formed therein, and covers 4 and 5 positioned to respectively cover both end portions of body 3. In this instance, one or more openings for injecting or exhausting reactant and inert gas may be formed in the cover 5 in one direction. Also, one or more channels corresponding to the positions of the one or more openings may be formed in the body 3. Each of the channels may be extended in the longitudinal direction of the cylinder-shaped body 3 to transport the reactant or inert gas into the body 3.

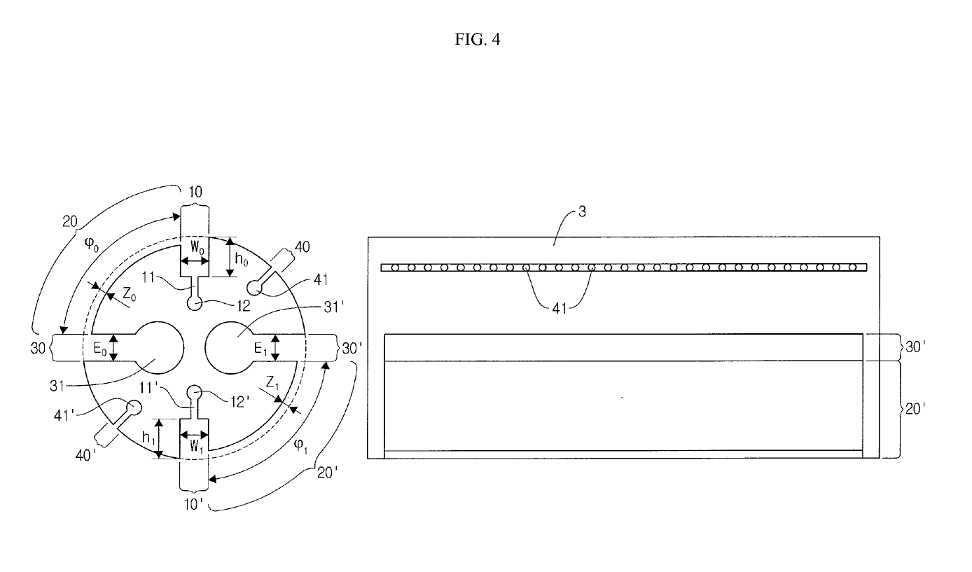

FIG. 4 illustrates cross-sectional and longitudinal sectional views of the vapor deposition reactor of FIG. 2A. One or more unit modules that perform injection and exhaust of a reactant and the like are formed in the body 3 of the vapor deposition reactor so as to form a thin film. That is, the vapor deposition reactor may include a unit module having first, second and third portions 10, 20 and 30 and another unit module having first, second and third portions 10′, 20′ and 30′. The vapor deposition reactor may further include fourth portions 40 and 40′ positioned adjacent to the respective unit modules.

Although the vapor deposition reactor is illustrated as including only two unit modules in FIGS. 4A and 4B, the number of unit module is merely an example. That is, the vapor deposition reactor may include one unit module or three or more unit modules.

The configurations of unit modules included in one vapor deposition reactor may be identical. For the sake of explanation, the configuration of a unit module having first, second and third portions 10, 20 and 30 will be described in detail. In the unit module, recesses or spaces respectively formed in the first, second and third portions 10, 20 and 30 may be communicatively connected to one another. One or more first injection portions 11 for injecting a reactant may be formed in the first portion 10. The one or more first injection portions 11 may be connected to a channel 12 along which the reactant is transported. An exhaust portion 31 for exhausting an extra reactant or the like from the vapor deposition reactor may be formed in the third portion 30.

Meanwhile, one or more second injection portions 41 for injecting an inert gas may be formed in the fourth portion 40. For example, Ar gas may be used as the inert gas. The one or more second injection portions 41 may be connected to a channel 42 through which the inert gas is transported. The inert gas injected by the one or more second injection portions 41 shields a material injected through the one or more first injection portions 11 and a material injected through another one or more first injection portions 11′ from each other. Also, the inert gas functions to remove a physical absorption layer such as a precursor, absorbed on a target curved surface while flowing through a gap between the body 3 of the vapor deposition reactor and the curved surface. The inert gas is exhausted to the exterior of the vapor deposition reactor through exhaust portions 31 and 31′ of the third portions 30 and 30′.

In the fourth portion 40 of FIG. 4, the one or more second injection portions 41 may be configured as holes formed in a slit-shaped recess extended along the length direction of the body 3 of the vapor deposition reactor. However, this is provided only for illustrative purposes. In another embodiment, the fourth portion 40 is not provided with a separate recess, and the one or more second injection portions 41 may be directly formed on the surface of the body 3 of the vapor deposition reactor. Alternatively, the second injection portion 41 may be configured as a slit-shaped recess extended along the longitudinal direction of the body 3 of the vapor deposition reactor.

The vapor deposition reactor described above is defined by, among others reactor parameters, the widths w₀ and w₁ and heights h₀ and h₁ of the respective first portions 10 and 10′, the heights z₀ and z₁ and lengths φ₁ and φ₂ of the respective second portions 20 and 20′, the widths E₀ and E₁ of the respective third portions 30 and 30′, and the length L of the body 3 of the vapor deposition reactor. Also, process parameters related to reaction include the flow rates v_{A} and v_{B} of the reactant injected through the one or more first injection portions 11 and 11′, the pumping speeds Ω_{A} and Ω_{B} through the exhaust portions 31 and 31′, the rotation speed w of the tube with respect to the vapor deposition reactor, the pressures P_{A0} and P_{B0} of the respective first portions 10 and 10′, the pressures P_{A1} and P_{B1} of the respective second portions 20 and 20′, the pressures P_{A2} and P_{B2} of the respective third portions 30 and 30′, the pressures P_{S0} and P_{S1} of the respective fourth portions 40 and 40′, and the like.

In one embodiment, the pressure P_{S0} or P_{S1} of each of the fourth portions 40 and 40′ of the vapor deposition reactor may be greater than those of other portions adjacent to each of the fourth portions 40 and 40′. That is, the pressure P₅₀ of the fourth portion 40 may be identical to or greater than the pressures P_{A0} and P_{B2} of the first and third portions 10 and 30′ adjacent to the fourth portion 40. The pressure P₅₁ of the fourth portion 40′ may be identical to or greater than the pressures P_{A2} and P_{B0} of the third and first portions 30 and 10′ adjacent to the fourth portion 40′. The pressure P_{A0} of the first portion 10 may be greater than the pressure P_{A1} of the second portion 20, and the pressure P_{A1} of the second portion 20 may be greater than the pressure P_{A2} of the third portion 30. Similarly, the pressure P_{B0} of the first portion 10′ may be greater than the pressure P_{B1} of the second portion 20′, and the pressure P_{B1} of the second portion 20′ may be greater than the pressure P_{B2} of the third portion 30′.

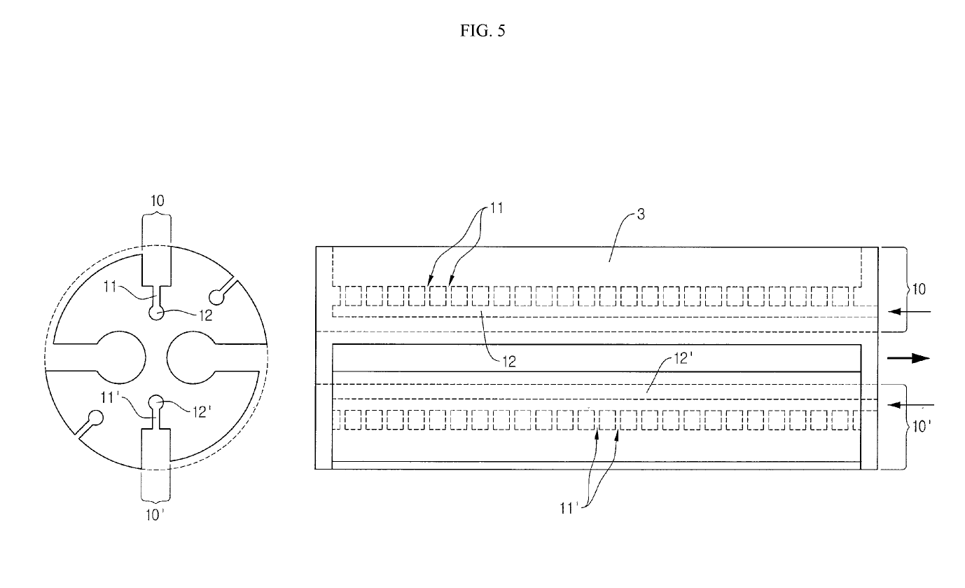

FIG. 5 illustrates cross-sectional and longitudinal sectional views of the vapor deposition reactor of FIG. 2A. The one or more first injection portions 11 and 11′ arranged along the length direction of the body 3 of the vapor deposition reactor may be formed in the respective first portions 10 and 10′. The one or more first injection portions 11 and 11′ may be extended along the length direction of the body 3 and connected to channels 12 and 12′ through which a reactant is transported. The reactant injected through the one or more first injection portions 11 may be identical to or different from that injected through the one or more first injection portions 11′.

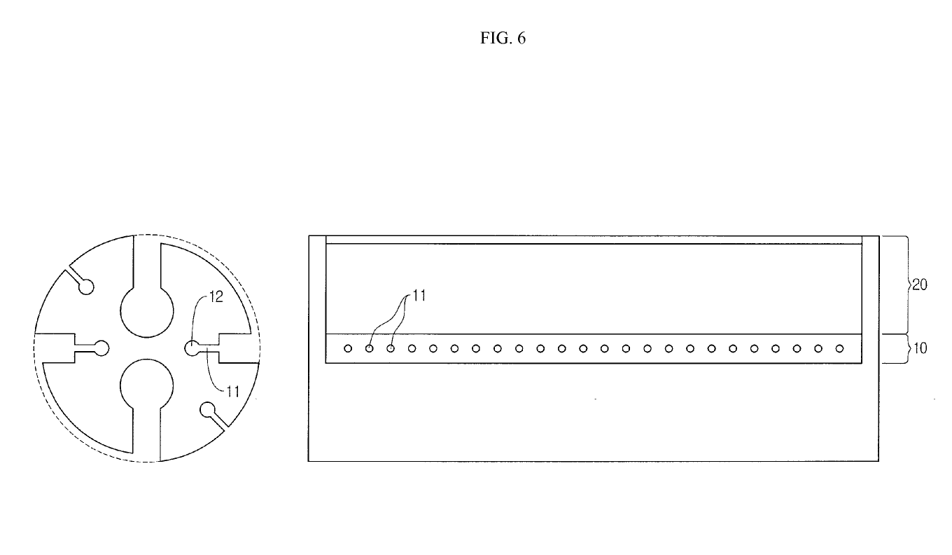

FIG. 6 illustrates cross-sectional and longitudinal sectional views of the vapor deposition reactor of FIG. 2A. The one or more first injection portions 11 in the first portion 10 may be formed in the shape of holes that are arranged at a certain interval and have a circular section. However, this is provided only for illustrative purposes. That is, the one or more first injection portions 11 may be formed in the shape of holes having a different section from the circular section.

Hereinafter, a method for forming a thin film using the vapor deposition reactor according to the aforementioned embodiment will be described with reference to FIGS. 2 to 6.

If the tube 2 is rotated in the state that the vapor deposition reactor 1 is inserted into the tube 2, the inner surface of the tube 2 may sequentially pass through the first, second and third portions 10, 20 and 30. The inner surface of the tube 2 is exposed to the inert gas while passing through the fourth portion 40 and then exposed to the reactant injected through the one or more first injection portions 11 while subsequently passing through the first portion 10. The injected reactant may form a physical absorption layer and a chemical absorption layer on the inner surface of the tube 2. Subsequently, while the inner surface of the tube 2 passes through the second portion 20, the physical absorption layer of the reactant may be at least partially desorbed due to the relatively low pressure of the second portion 20. Molecules of the desorbed reactant are discharged to the exterior of the vapor deposition reactor through the exhaust portion 31 while the inner surface of the tube 2 passes through the third portion 30.

Subsequently, the inner surface of the tube 2 may pass through the fourth portion 40′, the first portion 10′, the second portion 20′ and the third portion 30′. In this instance, the reactant injected through the one or more first injection portions 11′ of the first portion 10′ may react with the physical absorption layer of the reactant injected through the one or more first injection portions 11 of the first portion 10, thereby forming a thin film on the inner surface of the tube 2.

For example, an atomic layer deposition (ALD) thin film by the reaction of a source precursor and a reactant precursor may be formed on the inner surface of the tube 2 by injecting the source precursor through the one or more first injection portions 11 and injecting the reactant precursor through the one or more first injection portions 11′. Alternatively, a nanolayer having a thickness corresponding to several atomic layers may be formed on the inner surface of the tube 2 by leaving a portion of the physical absorption layer of the source precursor and/or the reactant precursor on the inner surface of the tube 2 without completely removing the physical absorption layer under the control of the reactor parameters.

As an example, an Al₂O₃ layer may be formed on the inner surface of the tube 2 by injecting trymethylaluminum (TMA) as the source precursor through the one or more first injection portions 11 and injecting H₂O₂ or O₃ as the reactant precursor through the one or more first injection portions 11′. As another example, a TiN layer may be formed on the inner surface of the tube 2 by injecting TiCl₄ as the source precursor through the one or more first injection portions 11 and injecting NH₃ as the reactant precursor through the one or more first injection portions 11′. In the aforementioned methods, the rotation speed of the tube 2 may be adjusted to be about 10 to 100 rpm. Also, Ar gas may be used as the inert gas injected through the one or more second injection portions 41 and 41′.

In still another example, a mixture of tetraethylmethylaminozirconium (TEMAZr) and tetraethylmethylaminosilicon (TEMASi) may be injected as the source precursor through the one or more first injection portions 11. The TEMAZr and TEMASi may be previously mixed together to be injected through the same first injection portions 11, or two kinds of first injection portions 11 for respectively injecting the TEMAZr and TEMASi are provided so that they are mixed together in the recess formed in the first portion 10. The H₂O₂ or O₃ may be injected as the reactant precursor through the one or more first injection portions 11′. As a result, a ZrₓSi₁₋ₓO₂ layer may be formed on the inner surface of the tube 2. The composition of the finally formed ZrₓSi₁₋ₓO₂ layer may be determined based on the mixture ratio of the TEMAZr and TEMASi used as the source precursor, the flow rates of the respective TEMAZr and TEMASi, the rate of the mixed source precursor, and the like. In this case, the rotation speed of the tube 2 may be adjusted to be about 10 to 100 rpm. Also, Ar gas may be used as the inert gas injected through the one or more second injection portions 41 and 41′.

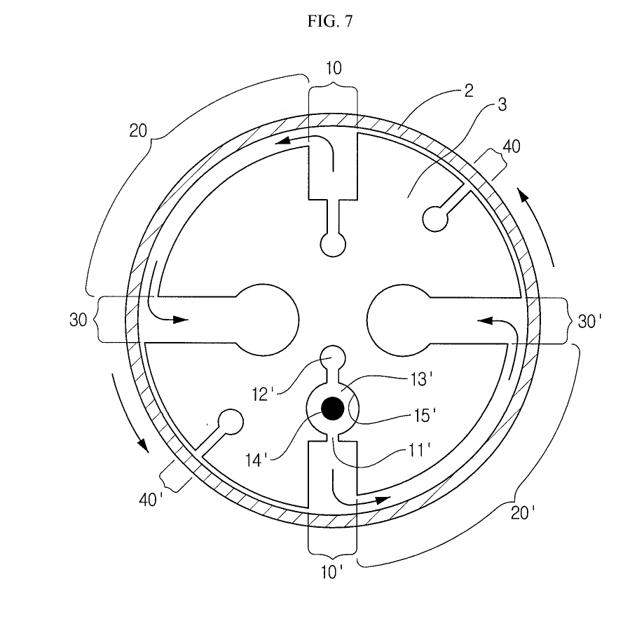

FIG. 7 is a cross-sectional view showing a vapor deposition reactor obtained by modifying the vapor deposition reactor according to the embodiment described with reference to FIGS. 2A to 6 to use plasma. A cavity 13′ connected to the one or more first injection portions 11′ may be further formed in any one of the first portions 10 and 10′ included in the vapor deposition reactor. A plurality of electrodes 14′ and 15′ for generating plasma may be positioned in the cavity 13′. In one embodiment, the plurality of electrodes 14′ and 15′ may include internal and external electrodes 14′ and 15′ having a concentric circular section so as to generate coaxial capacitive type plasma. However, this is provided only for illustrative purposes. In another embodiment, an electrode structure for generating different types of plasma such as induction coupled plasma (ICP) may be used.

The internal electrode 14′ may be an electrode that is positioned in the cavity 13′ and has a circular section. Meanwhile, if the body 3 of the vapor deposition reactor is made of a conductive material such as aluminum or inconel steel, a separate element is not used as the external electrode 15′, but a region adjacent to the internal electrode 14′ may be used as the external electrode 15′ in the body 3 of the vapor deposition reactor. In one embodiment, the cavity 13′ may be a space having a circular section with a diameter of about 10 to 20 mm, and a portion that defines the corresponding space in the body 3 of the vapor deposition reactor may correspond to the external electrode 15′. However, this is provided only for illustrative purposes. In another embodiment, one or more of the plurality of electrodes 14′ and 15′ may be separate elements made of a different material from the body 3 of the vapor deposition reactor.

Plasma may be generated in the cavity 13′ using the plurality of electrodes 14′ and 15′. To this end, DC voltage, pulse voltage or RF voltage may be applied across the plurality of electrodes 14′ and 15′. For example, a voltage of about 500 to 1500 V may be applied between the plurality of electrodes 14′ and 15′. As a result, a radical of the material injected through the one or more first injection portions 11′ may be generated, and radical-assisted ALD may be implemented using the radical. In this instance, the material injected through the one or more first injection portions 11′ may include an inert gas such as Ar gas and/or a reactant gas. The reactant gas may include an oxidizing gas such as O₂, N₂O and H₂O, a nitriding gas such as N₂ and NH₃, a carbonizing gas such as CH₄, or a reducing gas such as H₂, but is not limited thereto.

If a radical (e.g., Ar* radical) of the inert gas such as Ar gas is generated in the cavity 13′, a radical of the inert gas cuts the connection between molecules in the thin film formed on the inner surface of the tube 2 as a result of the preceding process, so that the deposition characteristic of the thin film can be improved in a subsequent process. Meanwhile, radicals (e.g., O* radicals, H* radicals or N* radicals) of the reactant gas such as O₂, N₂O, H₂O, N₂, NH₃, CH₄ or H₂ are generated in the cavity 13′, the generated radicals of the reactant gas may allow molecules or radicals absorbed on the inner surface of the tube 2 to be desorbed while being exhausted to the exterior of the vapor deposition reactor through the exhaust portion 31′ via the second and third portions 20′ and 30′. In the aforementioned process, the radicals (e.g., Ar* radicals, H* radicals or N* radicals) having a short life span may react with the material absorbed on the inner surface of the tube 2 for a certain period of time and then return to the inert state. The radicals returned to the inert state may remove excessively absorbed precursors from the inner surface of the tube 2 while being exhausted through the exhaust portion 31′.

In the embodiment shown in FIG. 7, the electrodes 14′ and 15′ for generating plasma and the cavity 13′ is provided to only the first portion 10′ of the two first portions 10 and 10′. However, this is provided only for illustrative purposes. In another embodiment, the electrode structure for generating plasma may be provided to both the two first portions 10 and 10′.

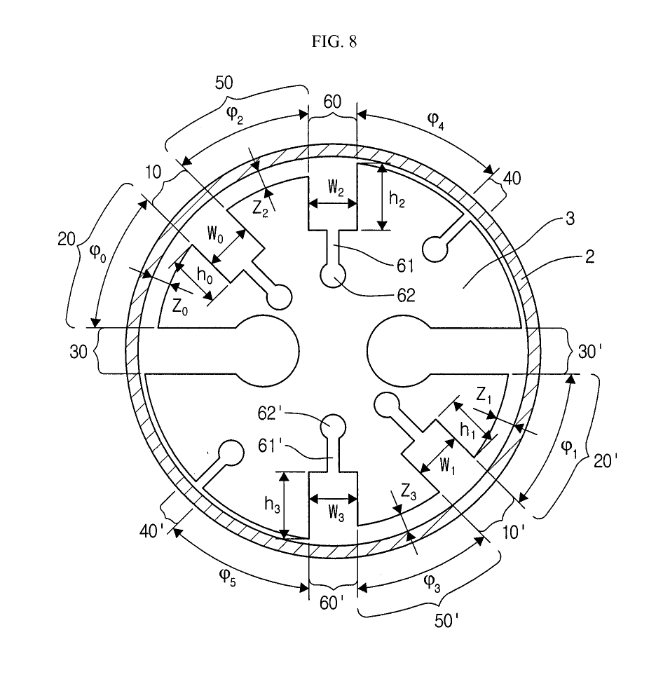

FIG. 8 is a sectional view of a vapor deposition reactor according to still another embodiment. In the descriptions of embodiments provided below, the descriptions of parts which those skilled in the art can readily understand from the precedingly described embodiments will be omitted, and only differences from the precedingly described embodiments will be described.

Referring to FIG. 8, in the vapor deposition reactor according to the embodiment, the unit modules may further include fifth portions 50 and 50′ positioned opposite to the second portions 20 and 20′ with the first portions 10 and 10′ interposed therebetween, respectively. A sixth portion 60 may be positioned adjacent to the fifth portion 50, and a sixth portion 60′ may be positioned adjacent to the fifth portion 50′. Recesses formed in the respective first, fifth and sixth portions 10, 50 and 60 may be communicatively connected to one another. Similarly, recesses formed in the respective first, fifth and sixth portions 10′, 50′ and 60′ may be communicatively connected to one another. One or more third injection portions 61 and 61′ for injecting a reactant may be formed in the respective sixth portions 60 and 60′. The one or more third injection portions 61 and 61′ may be connected to channels 62 and 62′ through which the reactant is transported.

If a thin film is formed using the vapor deposition reactor configured as described above, reactor parameters include the lengths φ₂ and φ₃ of the respective fifth portions 50 and 50′, the width and height of the sixth portion 60, the width w₃ and height h₃ of the sixth portion 60′, and the flow rate of the reactant injected through the one or more third injection portions 61 and 61′, in addition to the reactor parameters described with reference to FIG. 4.

Here, the lengths φ₀ and φ₂ of the second and fifth portions 20 and 50 may be determined at least partially based on the sticking coefficient or Van der Walls force of a material injected through the one or more first injection portions 11 and the one or more third injection portions 51. Similarly, the lengths φ₁ and φ₃ of the second and fifth portions 20′ and 50′ may be determined at least partially based on the sticking coefficient or Van der Walls force of a material injected through the one or more third injection portions 51′. In addition, the length φ₄ between the sixth portion 60 and the fourth portion 40 adjacent to the sixth portion 60 may be determined at least partially based on the vapor pressure and diffusivity of a reactant injected through the one or more third injection portions 61. Similarly, the length φ₅ between the sixth portion 60′ and the fourth portion 40′ adjacent to the sixth portion 60′ may be determined at least partially based on the vapor pressure and diffusivity of a reactant injected through the one or more third injection portions 61′.

In one embodiment, the pressure P_{A6} of the sixth portion 60 may be greater than the pressure P_{A5} of the fifth portion 50 adjacent to the sixth portion 60. The pressure P_{A5} of the fifth portion 50 may be greater than the pressure P of the third portion 30. Similarly, the pressure P_{B6} of the sixth portion 60′ may be greater than the pressure P_{B5} of the fifth portion 50′, and the pressure P_{B5} of the fifth portion 50′ may be greater than the pressure P_{B3} of the third portion 30′.

Hereinafter, a method for forming a thin film using the vapor deposition reactor according to the aforementioned embodiment will be described with reference to FIG. 8.

If the tube 2 is rotated in the state where the vapor deposition reactor 1 according to the embodiment shown in FIG. 8 is inserted into the tube 2, the inner surface of the tube 2 may sequentially pass through the fourth portion 40, the sixth portion 60, the fifth portion 50, the first portion 10, the second portion 20 and the third portion 30. In this instance, a reactant may be injected through the one or more third injection portions 61 of the sixth portion 60, and an inert gas may be injected through the one or more first injection portions 11 of the first portion 10. For example, a source precursor may be injected through the one or more third injection portions 61, and Ar gas may be injected through the one or more first injection portions 11. Extra source precursor molecules and Ar gas are exhausted through the exhaust portion 31 of the third portion 30. As a result, chemisorbed molecules of the source precursor are left on the inner surface of the tube 2 that passes through the third portion 30.

Subsequently, the inner surface of the tube 2 may sequentially pass through the fourth portion 40′, the sixth portion 60′, the fifth portion 50′, the first portion 10′, the second portion 20′ and the third portion 30′. In this instance, a reactant precursor may be injected through the one or more third injection portions 61′ of the sixth portion 60′, and Ar gas may be injected through the one or more first injection portions 11′ of the first portion 10′. The reactant precursor is reacted to the chemisorbed molecules of the source precursor formed on the inner surface of the tube 2 to form a thin film, and extra source precursor molecules, reactant precursor molecules and/or Ar gas, left after the reaction, may be exhausted to the exterior of the vapor deposition reactor through the exhaust portion 31′.

According to the method for forming a thin film described above, the inert gas such as Ar gas is injected through the one or more first injection portions 11 and 11′, and thus, removes physisorbed molecules of the source precursor or reactant precursor absorbed on the inner surface of the tube 2. As a result, the finally formed thin film can be obtained in the form of a mono atomic layer.

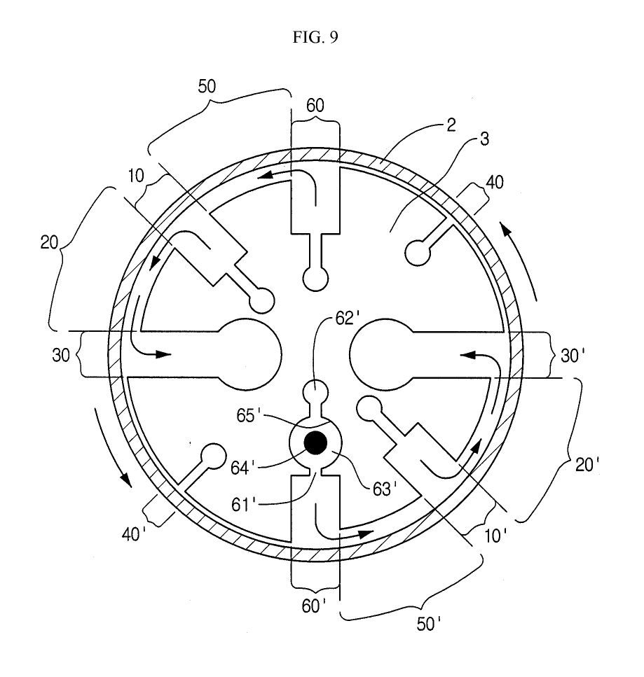

FIG. 9 is a cross-sectional view of a vapor deposition reactor obtained by modifying the vapor deposition reactor according to the embodiment described with reference to FIG. 8 to use plasma.

Referring to FIG. 9, a cavity 63′ connected to the one or more third injection portions 61′ may be further formed in the sixth portion 60′ of the sixth portions 60 and 60′ included in the vapor deposition reactor. A plurality of electrodes 64′ and 65′ for generating plasma may be positioned in the cavity 63′. For example, the plurality of electrodes 64′ and 65′ may include internal and external electrodes 64′ and 65′ having a concentric circular section so as to generate coaxial capacitive type plasma. However, this is provided only for illustrative purposes. That is, an electrode structure for generating different type plasma such as induction coupled plasma (ICP) may be used.

The operation of the vapor deposition reactor according to the embodiment shown in FIG. 9 is similar to the embodiment of FIG. 7, and therefore, its detailed description is omitted herein for the sake of brevity.

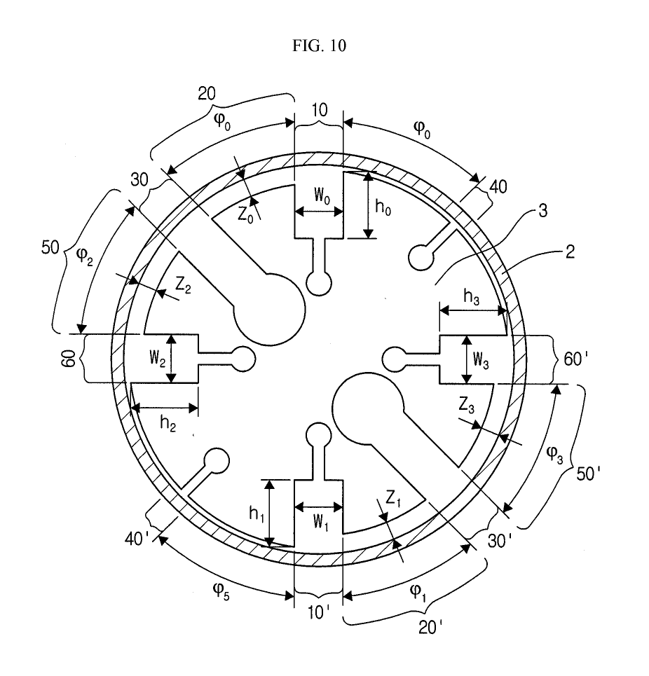

FIG. 10 is a sectional view of a vapor deposition reactor according to still another embodiment. The unit modules may further include fifth portions 50 and 50′ positioned opposite to the second portions 20 and 20′ with the third portions 30 and 30′ interposed therebetween, respectively. A sixth portion 60 may be positioned adjacent to the fifth portion 50, and a sixth portion 60′ may be positioned adjacent to the fifth portion 50′. Recesses formed in the respective third, fifth and sixth portions 30, 50 and 60 may be communicatively connected to one another. Similarly, recesses formed in the respective third, fifth and sixth portions 30′, 50′ and 60′ may be communicatively connected to one another. One or more third injection portions 61 and 61′ for injecting a reactant may be formed in the respective sixth portions 60 and 60′. The one or more third injection portions 61 and 61′ may be connected to channels 62 and 62′ through which the reactant is transported.

Hereinafter, a method for forming a thin film using the vapor deposition reactor according to the embodiment described with reference to FIG. 10 will be described.

If the tube 2 is rotated in the state where the vapor deposition reactor 1 according to the embodiment shown in FIG. 10, the inner surface of the tube 2 may sequentially pass through the fourth portion 40, the first portion 10, the second portion 20, the third portion 30, the fifth portion 50 and the sixth portion 60. In this instance, a reactant may be injected through the one or more first injection portions 11, and an inert gas such as Ar gas may be injected through the one or more third injection portions 61. Extra source precursor and Ar gas may be exhausted through the exhaust portion 31′ positioned in the middle of the tube 2. As a result, chemisorbed molecules of a source precursor are left on the inner surface of the tube 2 that passes through the sixth portion 60.

Subsequently, the inner surface of the tube 2 may sequentially pass through the fourth portion 40′, the first portion 10′, the second portion 20′, the third portion 30′, the fifth portion 50′ and the sixth portion 60′. In this instance, a reactant precursor may be injected through the one or more first injection portions 11′, and Ar gas may be injected through the one or more third injection portions 61′. The reactant precursor is reacted to the chemisorbed molecules of the source precursor formed on the inner surface of the tube 2 to form a thin film, and excess precursor and Ar gas, left after the reaction, may be exhausted to the exterior of the vapor deposition reactor through the exhaust portion 31′ positioned in the middle of the tube 2.

In the vapor deposition reactor shown in FIG. 10, the second portions 20 and 20′ and fifth portions 50 and 50′ for gas constriction and skimming are positioned at both sides of the third portions 30 and 30′ having the exhaust portions 31 and 31′ formed therein, respectively. The unit modules are separated by the fourth portions 40 and 40′ for injecting the inert gas. As a result, physisorbed molecules formed on the inner surface of the tube 2 and the inert gas can be easily desorbed and exhausted, and a mono atomic layer can be obtained.

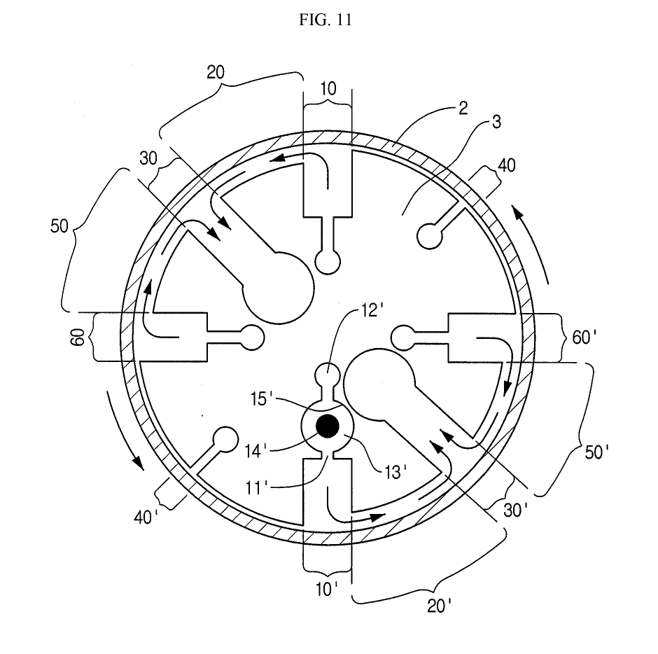

FIG. 11 is a cross-sectional view of a vapor deposition reactor obtained by modifying the vapor deposition reactor according to the embodiment described with reference to FIG. 10 to use plasma. A cavity 63′ connected to the one or more third injection portions 61′ may be further formed in the sixth portion 60′ of the sixth portions 60 and 60′ included in the vapor deposition reactor. A plurality of electrodes 64′ and 65′ for generating plasma may be positioned in the cavity 63′. The operation of the vapor deposition reactor according to the embodiment shown in FIG. 11 is omitted herein for the sake of brevity.

In the embodiments shown in FIGS. 9 and 11, an apparatus for generating plasma is formed in only the sixth portion 60′ of the two sixth portions 60 and 60′. However, this is provided only for illustrative purposes. In another embodiment, an electrode structure for generating plasma may be applied to both the two sixth portions 60 and 60′.

In still another embodiment, the electrode structure for generating plasma may be applied to the first portion 10′ in addition to the sixth portion 60′. In this case, radicals of the reactant precursor may be injected through the one or more third injection portions 61′ formed in the sixth portion 60′, and radicals of the inert gas may be injected through the one or more first injection portions 11′ formed in the first portion 10′. In this instance, the radical of the inert gas cut the connection between molecules in the thin film formed on the inner surface of the tube 2 as a result of the preceding process, so that the deposition characteristic of the thin film can be improved in a subsequent process.

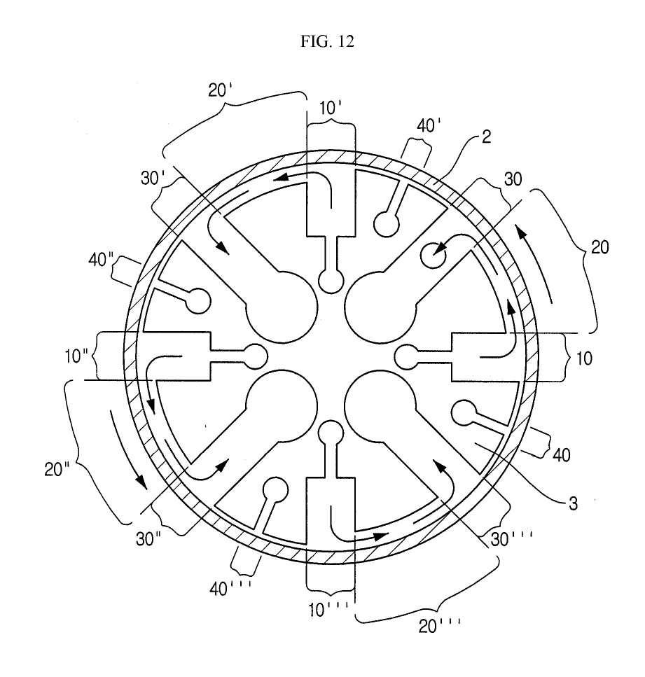

FIG. 12 is a cross-sectional view of a vapor deposition reactor according to still another embodiment. The vapor deposition reactor may include four unit modules for injection and exhaustion of a reactant, and the like. Each of the unit modules may include first to third portions, and a fourth portion for injecting an inert gas may be positioned between the unit modules. That is, the vapor deposition reactor may include four first portions 10, 10′, 10″ and 10″′, four second portions 20, 20′, 20″ and 20′″, four third portions 30, 30′, 30″ and 30′″, and four fourth portions 40, 40′, 40″ and 40″′. The detailed configuration of each of the portions is identical to that of the vapor deposition reactor according to the embodiment described with reference to FIGS. 2 to 6. Therefore, its detailed description will be omitted.

Hereinafter, embodiments of the method for forming a thin film shown in FIG. 12 will be described.

In one embodiment, TMA may be injected as a source precursor through one or more first injection portions formed in the first portion 10 and the first portion 10″, and H₂O or O₃ may be injected as a reactant precursor through one or more first injection portions formed in the first portion 10′ and the first portion 10″′. In this instance, the tube may be rotated at a rotation speed of about 10 to 100 rpm. As a result, two Al₂O₃ layers may be formed on the inner surface of the tube 2 whenever the tube 2 is rotated once around the vapor deposition reactor.

In another embodiment, TMA may be injected as a source precursor through the one or more first injection portions formed in the first portion 10, and tetraethylmethyaminotitanium (TEMATi) may be injected as another source precursor through the one or more first injection portions formed in the first portion 10″. H₂O or O₃ may be injected as a reactant precursor through the one or more first injection portions formed in the first portion 10′ and the first portion 10″′. In this instance, the tube 2 may be rotated at a rotation speed of about 10 to 100 rpm. As a result, a thin film obtained by nano-laminating an Al₂O₃ layer and a TiO₂ layer may be formed on the inner surface of the tube 2 whenever the tube 2 is rotated once around the vapor deposition reactor.

In still another embodiment, tetraethylmethylaminozirconium (TEMAZr) may be injected as a source precursor through the one or more first injection portions formed in the first portion 10, and tetraethylmethylaminosilicon (TEMASi) may be injected as another source precursor through the one or more first injection portions formed in the first portion 10″. H₂O or O₃ may be injected as a reactant precursor through the one or more first injection portions formed in the first portion 10′ and the first portion 10″′. In this instance, the tube 2 may be rotated at a rotation speed of about 10 to 100 rpm. As a result, a thin film obtained by nano-laminating a ZrO₂ layer and a SiO₂ layer may be formed on the inner surface of the tube 2 whenever the tube 2 is rotated once around the vapor deposition reactor.

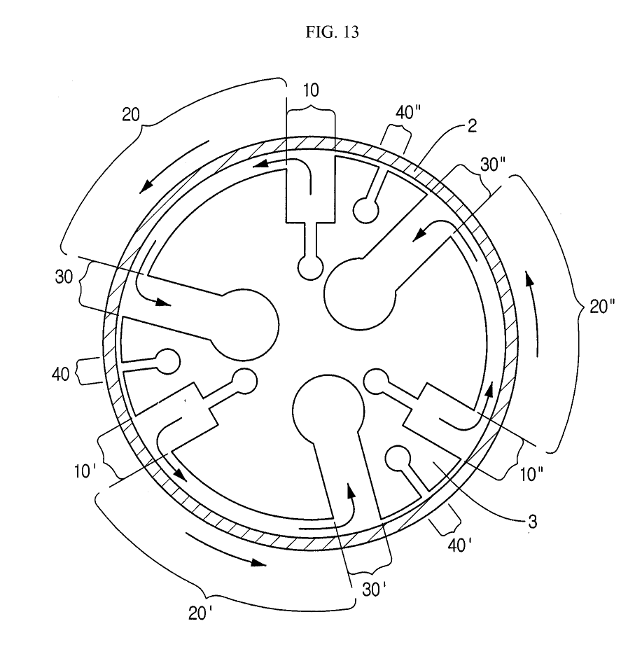

FIG. 13 is a cross-sectional view of a vapor deposition reactor according to still another embodiment.

Referring to FIG. 13, the vapor deposition reactor according to the embodiment may include three unit modules for injection and exhaustion of a reactant, and the like, and each of the unit modules may include first to third portions. A fourth portion for injecting an inert gas may be positioned between the unit modules. That is, the vapor deposition reactor may include three first portions 10, 10′ and 10″, three second portions 20, 20′ and 20″, three third portions 30, 30′ and 30″, and three fourth portions 40, 40′ and 40″.

As an example of the method of forming a thin film using the vapor deposition reactor shown in FIG. 13, TEMAZr may be injected as a source precursor through one or more first injection portions formed in the first portion 10, and TEMASi may be injected as another source precursor through one or more first injection portions formed in the first portion 10′. H₂O or O₃ may be injected as a reactant precursor through one or more first injection portions formed in the first portion 10″. In this instance, the tube 2 may be rotated at a rotation speed of about 10 to 100 rpm. As a result, a homogeneous layer made of ZrₓSi₁₋ₓO₂ may be formed on the inner surface of the tube 2 whenever the tube 2 is rotated once around the vapor deposition reactor.

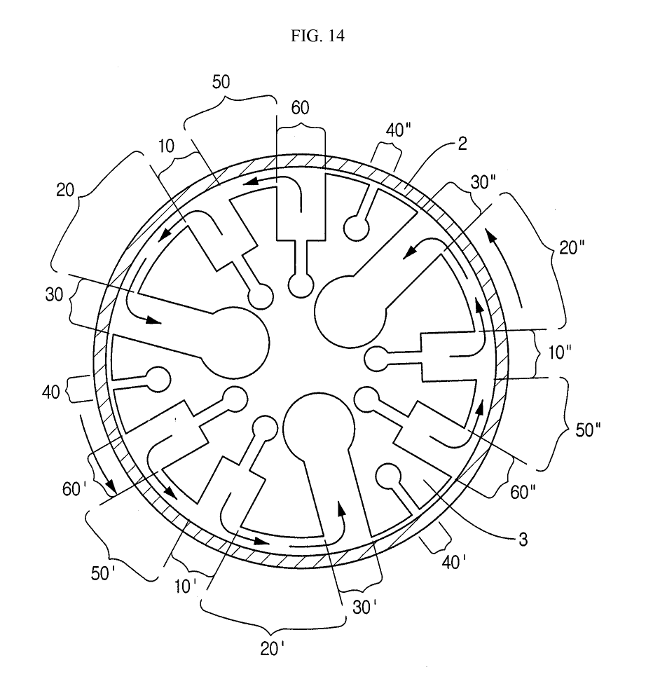

FIG. 14 is a cross-sectional view of a vapor deposition reactor according to still another embodiment. The vapor deposition reactor may include three unit modules for injection and exhaustion of a reactant, and the like. Each of the unit modules may include first, second third, fifth and sixth portions. A fourth portion for injecting an inert gas may be positioned between the unit modules. That is, the vapor deposition reactor may include three first portions 10, 10′ and 10″, three second portions 20, 20′ and 20″, three third portions 30, 30′ and 30″, three fourth portions 40, 40′ and 40″, three fifth portions 50, 50′ and 50″, and three sixth portions 60, 60′ and 60″. The detailed configuration of each of the portions is identical to that of the vapor deposition reactor described with reference to FIG. 8, and therefore, its detailed description will be omitted.

Hereinafter, embodiments of the method for forming a thin film shown in FIG. 14 will be described.

In one embodiment, TEMAZr may be injected as a source precursor through one or more third injection portions formed in the sixth portion 60, and TEMASi may be injected as another source precursor through one or more third injection portions formed in the sixth portion 60′. H₂O or O₃ may be injected as a reactant precursor through one or more third injection portions formed in the sixth portion 60″. In this instance, an inert gas such as Ar gas may be injected through one or more first injection portions formed in each of the first portions 10, 10′ and 10″. The tube 2 may be rotated at a rotation speed of about 10 to 100 rpm. As a result, a homogeneous layer made of ZrₓSi₁₋ₓO₂ may be formed on the inner surface of the tube 2 whenever the tube 2 is rotated once around the vapor deposition reactor.

In another embodiment, TEMAZr may be injected as a source precursor through the one or more third injection portions formed in the sixth portion 60 and the sixth portion 60′, and TEMASi may be injected as another source precursor through the one or more first injection portions formed in the first portion 10 and the first portion 10′. H₂O or O₃ may be injected as a reactant precursor through the one or more third injection portions formed in the sixth portion 60″. The tube 2 may be rotated at a rotation speed of about 10 to 100 rpm. As a result, a homogeneous layer made of ZrₓSi₁₋ₓO₂ may be formed on the inner surface of the tube 2 whenever the tube 2 is rotated once around the vapor deposition reactor.

In this instance, H₂O or O₃, or an inert gas such as Ar gas may be injected through the one or more first injection portions formed in the first portion 10″. If H₂O or O₃ is injected through the one or more first injection portions formed in the first portion 10″, oxygen concentration can be increased in the finally formed ZrₓSi₁₋ₓO₂ layer. On the other hand, in a case where Ar gas is injected through the one or more first injection portions formed in the first portion 10″, oxygen concentration can be decreased in the finally formed ZrₓSi₁₋ₓO₂ layer.

The method for forming a thin film described above has been described based on a vapor deposition reactor including three unit modules of the vapor deposition reactor according to the aforementioned embodiment. However, this is provided only for illustrative purposes. That is, the aforementioned methods for forming a thin film may be performed using a vapor deposition reactor different from the aforementioned vapor deposition reactor. For example, the aforementioned methods for forming a thin film may be formed using a vapor deposition reactor including three unit modules of the vapor deposition reactor according to the embodiment described with reference to FIG. 10.

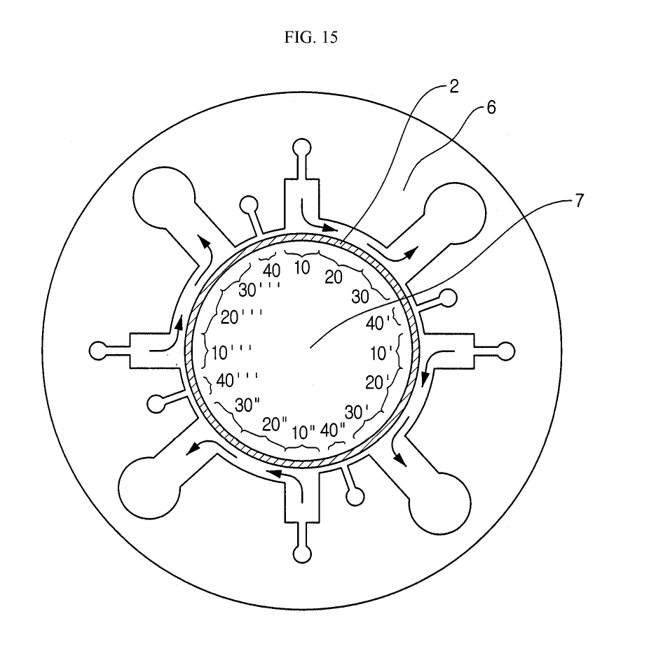

FIG. 15 is a cross-sectional view of a vapor deposition reactor according to still another embodiment. The vapor deposition reactor may include a body 6 having a hole 7 formed therein. For example, the body 6 of the vapor deposition reactor may have the shape of a cylinder in which the hole 7 with a circular section is formed. The vapor deposition reactor may further include one or more unit modules for injection and exhaustion of a reactant, which are arranged on the surface of the hole 7. Each of the unit modules may include first portions 10, 10′, 10″ and 10″′, second portions 20, 20′, 20″ and 20″′, and third portions 30, 30′, 30″ and 30″′. Fourth portions 40, 40′, 40″ and 40″′ may be positioned between the unit modules.

The tube 2 for depositing a thin film may be inserted into the hole 7 of the body 6 of the vapor deposition reactor. The first portions 10, 10′, 10″ and 10″′, the second portions 20, 20′, 20″ and 20″′, the third portions 30, 30′, 30″ and 30″″, and the fourth portions 40, 40′, 40″ and 40″′ in the vapor deposition reactor are arranged toward the exterior wall of the tube 2, so that a thin film can be formed on the exterior wall of the tube 2 as the vapor deposition reactor and the tube 2 are relatively moved. The detailed configuration of the vapor deposition reactor is similar to the vapor deposition reactor of FIGS. 2 to 6; and hence, the detailed description of the configuration is omitted herein for the sake of brevity.

Hereinafter, a method for forming a thin film using the vapor deposition reactor according to the embodiment described with reference to FIG. 15 will be described.

As an example, TMA may be injected as a source precursor through one or more first injection portions formed in the first portion 10 and the first portion 10″, and H₂O or O₃ may be injected as a reactant precursor through one or more third injection portions formed in the first portion 10′ and the first portion 10″′. In this instance, the tube 2 may be rotated at a rotation speed of about 10 to 100 rpm. As a result, two Al₂O₃ layers may be formed on the exterior wall of the tube 2 whenever the tube 2 is rotated once in the vapor deposition reactor.

As another example, TMA may be injected as a source precursor through the one or more first injection portions formed in the first portion 10, and H₂O or O₃ may be injected as a reactant precursor through the one or more third injection portions formed in the first portion 10′. Also, TiCl₄ may be injected as another source precursor through the one or more first injection portions formed in the first portion 10″, and NH₃ may be injected as another reactant precursor through the one or more third injection portions formed in the first portion 10″′. As a result, a thin film obtained by alternately laminating an Al₂O₃ layer and a TiN layer may be formed on the exterior wall of the tube 2 whenever the tube 2 is rotated once in the vapor deposition reactor.

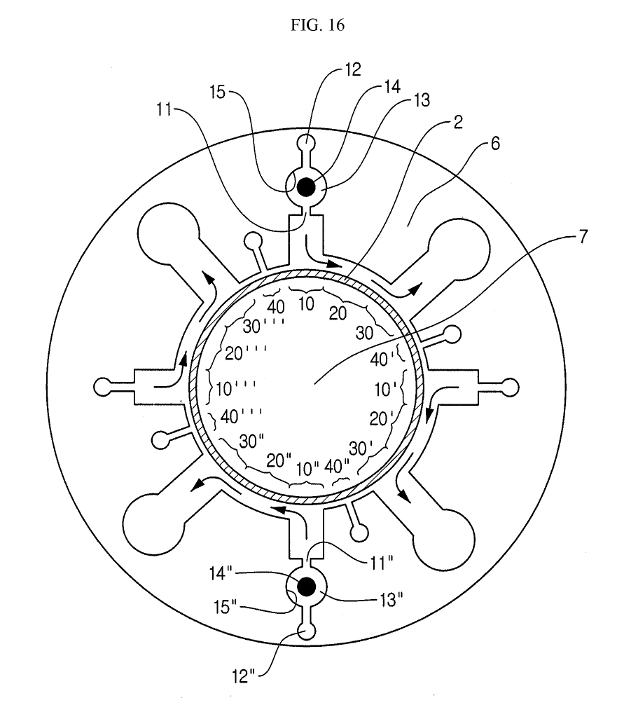

FIG. 16 is a cross-sectional view of a vapor deposition reactor obtained by modifying the vapor deposition reactor according to the embodiment described with reference to FIG. 15 to use plasma. An apparatus for generating plasma may be formed in some or all of the first portions 10, 10′, 10″ and 10″′ included in the vapor deposition reactor. For example, cavities 13 and 13″ for generating plasma and a plurality of electrodes 14, 14″, 15 and 15″ for generating plasma may be formed in the first portion 10 and the first portion 10″, respectively. In this case, a radical of the reactant may be generated using plasma from the reactant injected through the one or more first injection portions formed in the first portion 10 and the first portion 10″. Alternatively, a radical of the inert gas may be generated using plasma from the inert gas injected through the one or more first injection portions.

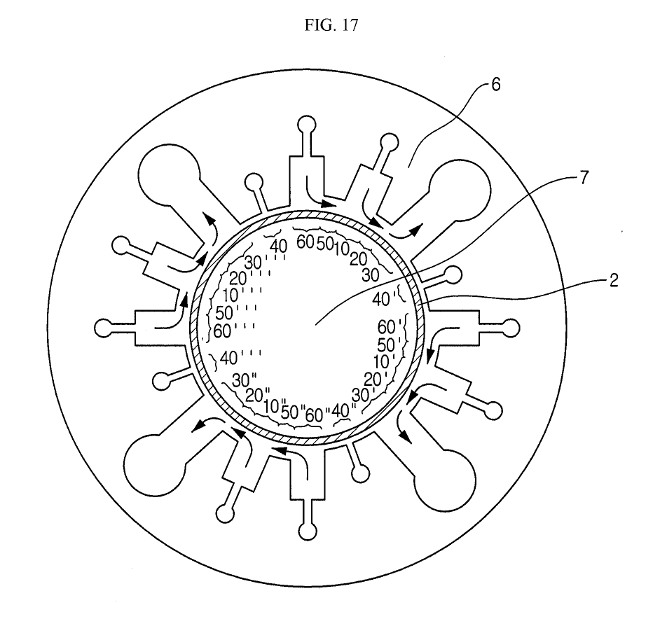

FIG. 17 is a cross-sectional view of a vapor deposition reactor according to still another embodiment. The vapor deposition reactor may include a body 6 having a hole 7 formed therein. The vapor deposition reactor may further include one or more unit modules for injection and exhaustion of a reactant, which are arranged along the surface of the hole 7. Each of the unit modules may include first portions 10, 10′, 10″ and 10″′, second portions 20, 20′, 20″ and 20″′, third portions 30, 30′, 30″ and 30′″, fifth portions 50, 50′, 50″ and 50′″, and sixth portions 60, 60′, 60″ and 60″. Fourth portions 40, 40′, 40″ and 40′″ for injecting an inert gas may be positioned between the unit modules. The detailed configuration of each of the portions is omitted herein for the sake of brevity.

Hereinafter, the method for forming a thin film using the vapor deposition reactor according to the embodiment described with reference to FIG. 17 will be described.

As an example, a mixture of TEMAZr and TEMASi may be injected as a source precursor through one or more third injection portions formed in the sixth portion 60 and the sixth portion 60″. In this instance, the TEMAZr and TEMASi may be previously mixed together to be injected through the same third injection portion, or two kinds of third injection portions for respectively injecting the TEMAZr and TEMASi are provided so that they are mixed together in recesses formed in the sixth portion 60 and the sixth portion 60″. H₂O or O₃ may be injected as a reactant precursor through one or more third injection portions formed in the sixth portion 60′ and the sixth portion 60″′. In this instance, an inert gas such as Ar gas may be injected through the one or more third injection portions formed in each of the first portions 10, 10′, 10″ and 10″′. As a result, two ZrₓSi₁₋ₓO₂ layers may be formed on the exterior wall of the tube 2 whenever the tube 2 is rotated once in the vapor deposition reactor.

As another example, a mixture of TEMAZr and TEMASi may be injected as a source precursor through the one or more third injection portions formed in the sixth portion 60, and H₂O or O₃ may be injected as a reactant precursor through the one or more third injection portions formed in the sixth portion 60′. Meanwhile, TEMASi may be injected as another source precursor through the one or more third injection portions formed in the sixth portion 60″, and NH₃ may be injected as another reactant precursor through the one or more third injection portions formed in the sixth portion 60″. As a result, a thin film including a ZrₓSi₁₋ₓO₂ layer and a SiN layer may be formed on the exterior wall of the vapor deposition reactor whenever the tube 2 is rotated once around the tube 2.

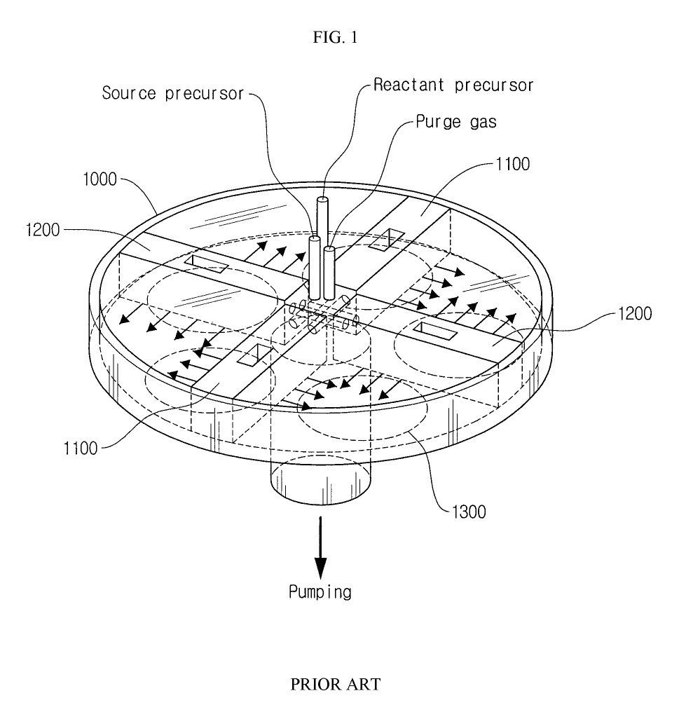

In the vapor deposition reactor according to the embodiment described with reference to FIG. 17, the arrangement of the components correspond to that in the vapor deposition reactor according to the aforementioned embodiment described with reference to FIG. 1, except the difference that the components are not arranged at the inside of the tube 2 but arranged at the outside of the tube 2. However, this is provided only for illustrative purposes. In another embodiment, the vapor deposition reactor may have an arrangement different from the aforementioned arrangement. For example, the vapor deposition reactor is configured by arranging the components at the outside of the tube 2 based on the arrangement of the components in the vapor deposition reactor according to the aforementioned embodiment described with reference to FIG. 10.

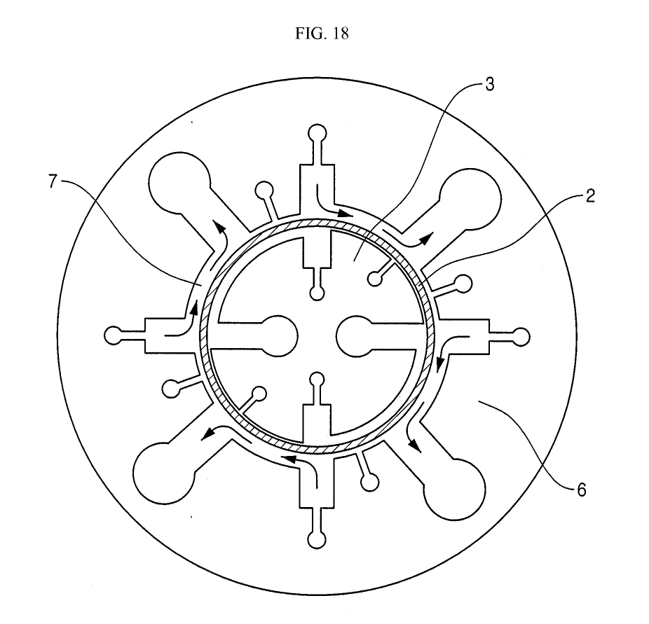

FIG. 18 may include a vapor deposition reactor according to still another embodiment. Referring to FIG. 18, a thin film may be simultaneously formed on the inner surface and exterior wall of a tube by combining two kinds of vapor deposition reactors. That is, the vapor deposition reactor according to the embodiment may include two bodies 3 and 6. One body 3 may be formed in the shape of a cylinder, and may be at least partially injected into a tube 2 on which the thin film is to be deposited. Meanwhile, the other body 6 may have a hole 7, and the tube 2 on which the thin film is to be deposited may be inserted into the hole 7. The thin film may be simultaneously formed on the inner surface and exterior wall of the tube 2 using one or more injection portions and exhaustion portions formed in the respective bodies 3 and 6.

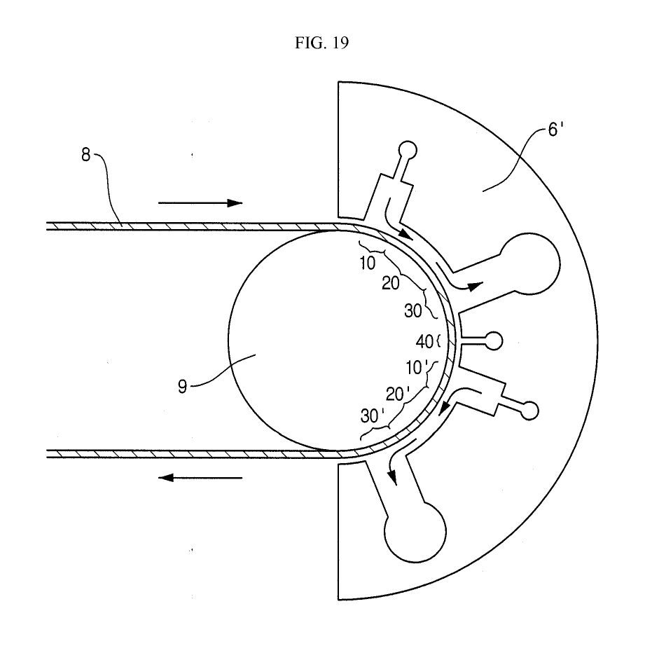

FIG. 19 may include a vapor deposition reactor according to still another embodiment. Referring to FIG. 19, a thin film may be formed on a flexible substrate 8 using the vapor deposition reactor according to the embodiment. In this instance, the flexible substrate 8 may be a roll plastic film, stainless steel foil, graphite foil or proper member having flexibility. The flexible substrate 8 may be partially wound around a roller 9 to be relatively moved with respect to the vapor deposition reactor.

A body 6′ of the vapor deposition reactor may be positioned to at least partially surround the flexible substrate 8 transported by the roller 9. The section of the body 6′ may have the shape of a portion of the circle (e.g., a semicircle). A thin film may be formed on the flexible substrate 8 while the flexible substrate 8 sequentially passes through a first portion 10, a second portion 20, a third portion 30, a fourth portion 40, a first portion 10′, a second portion 20′ and a third portion 30′, formed in the body 6′. This can be readily understood by those skilled in the art, and therefore, its detailed description will be omitted.

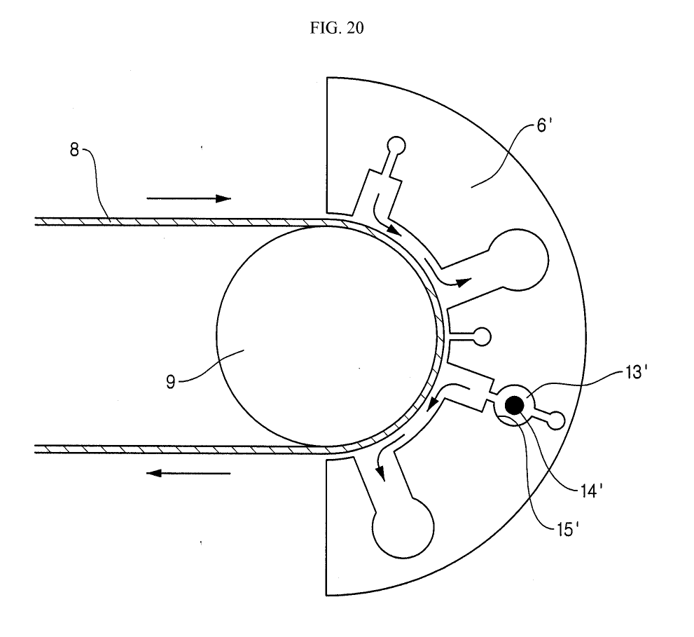

FIG. 20 is a cross-sectional view of a vapor deposition reactor obtained by modifying the vapor deposition reactor according to the embodiment described with reference to FIG. 19 to use plasma. An apparatus for generating plasma may be formed in one or both of the first portions 10 and 10′ included in the vapor deposition reactor. For example, a cavity 13′ for generating plasma and a plurality of electrodes 14′ and 15′ for generating plasma may be formed in the first portion 10′. In this case, a radical of a reactant may be generated using plasma from the reactant injected through one or more first injection portions formed in the first portion 10′. Alternatively, a radical of an inert gas may be generated using plasma from the inert gas injected through the one or more first injection portions.

In the embodiments shown in FIGS. 19 and 20, each of the vapor deposition reactor is configured by disposing the fourth portion 40 between unit modules including the first portions 10 and 10′, the second portions 20 and 20′, and the third portions 30 and 30′. Here, the arrangement of the unit modules is provided only for illustrative purposes. That is, the unit modules may be configured based on the arrangement of the unit modules in the vapor deposition reactor according to any one of the embodiments described in this specification.

For example, as shown in FIG. 8, each of the unit modules may have a structure in which the sixth portion, the fifth portion, the first portion, the second portion and the third portion are sequentially connected. Alternatively, as shown in FIG. 8, each of the unit modules may have a structure in which the first portion, the second portion, the third portion, the fifth portion and the sixth portions are sequentially connected. In this instance, a cavity for generating plasma and a plurality of electrodes for generating plasma may be formed in the one or more first portions and the one or more sixth portions.

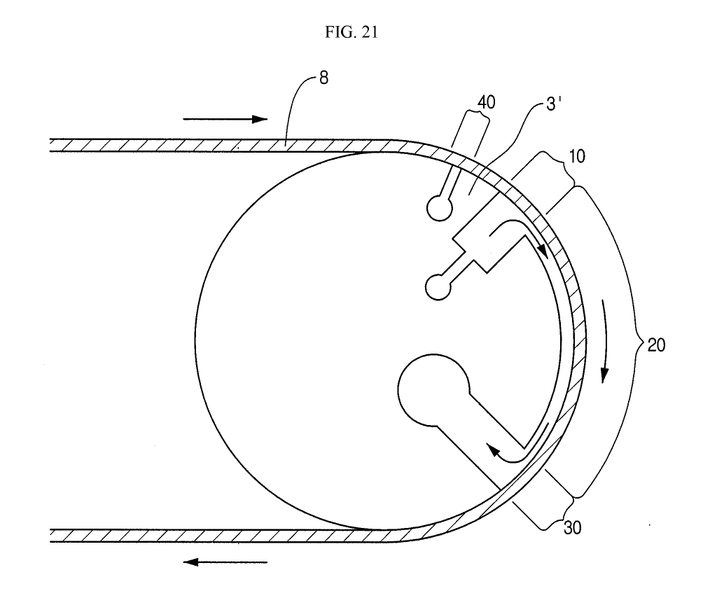

FIG. 21 is a cross-sectional view of a vapor deposition reactor according to still another embodiment. A body 3′ of the vapor deposition reactor according to the embodiment may be configured to transport a flexible substrate 8. For example, the body 3′ may have the shape of a cylinder, and the flexible substrate 8 may be configured to be transported while being wound around the body 3′. That is, the body 3′ of the vapor deposition reactor may serve as a roller that transports the flexible substrate 8. A thin film may be formed by injecting a reactant on the surface of the flexible substrate 8 while the flexible substrate 8 sequentially passes through a fourth portion 40, a first portion 10, a second portion 20 and a third portion 30 in the vapor deposition reactor.

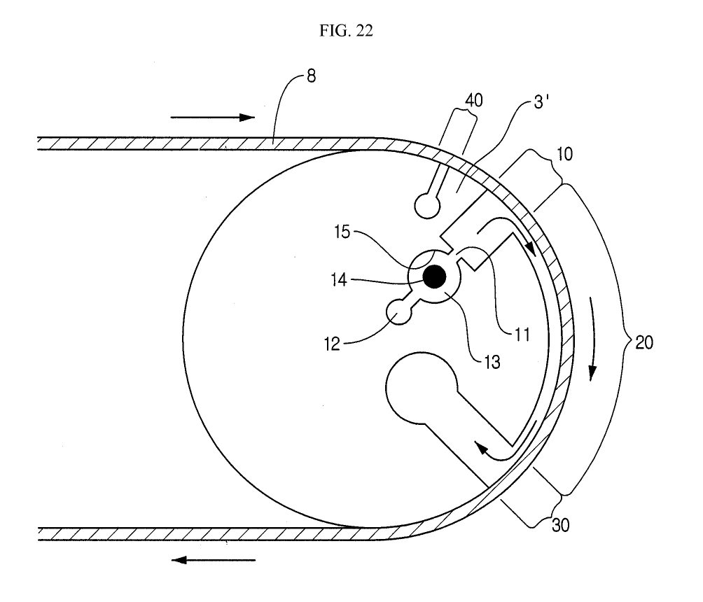

FIG. 22 is a cross-sectional view of a vapor deposition reactor obtained by modifying the vapor deposition reactor according to the embodiment described with reference to FIG. 21 to use plasma. An apparatus for generating plasma may be formed in the first portion 10 of the vapor deposition reactor. For example, a cavity 13 for generating plasma and a plurality of electrodes 14 and 15 for generating plasma may be formed in the first portion 10. In this case, a radical of a reactant may be generated using plasma from the reactant injected through one or more first injection portions formed in the first portion 10. Alternatively, a radical of an inert gas may be generated using plasma from the inert gas injected through the one or more first injection portions.

In the embodiments shown in FIGS. 21 and 22, the vapor deposition reactor includes a unit module having first, second and third portions 10, 20 and 30, and a fourth portion 40 adjacent to the first portion 10. However, this is provided only for illustrative purposes. In another embodiment, the vapor deposition reactor may further include an additional fourth portion (not shown) positioned adjacent to the third portion 30. In this case, since the forth portion for injecting an inert gas is positioned at both ends of the unit module, it is possible to minimize the influence of ambient environment on the unit module and the leakage of the reactant. In still another embodiment, the vapor deposition reactor does not include the fourth portion 40 but may include only the first portion 10, the second portion 20 and the third portion 30. In this case, since a physical absorption layer of the reactant is partially left on the flexible substrate 8, a nanolayer including a plurality of mono-atomic layers may be formed on the surface of the flexible substrate 8.

In the embodiments described with reference to FIGS. 21 and 22, the unit module of the vapor deposition reactor has the arrangement of the first portion 10, the second portion 20 and the third portion 30. However, this is provided only for illustrative purposes. That is, the unit module of the vapor deposition reactor may have a configuration corresponding to the unit module of the vapor deposition reactor according to any one of the embodiments described in this specification. Alternatively, the vapor deposition reactor may include a plurality of unit modules.

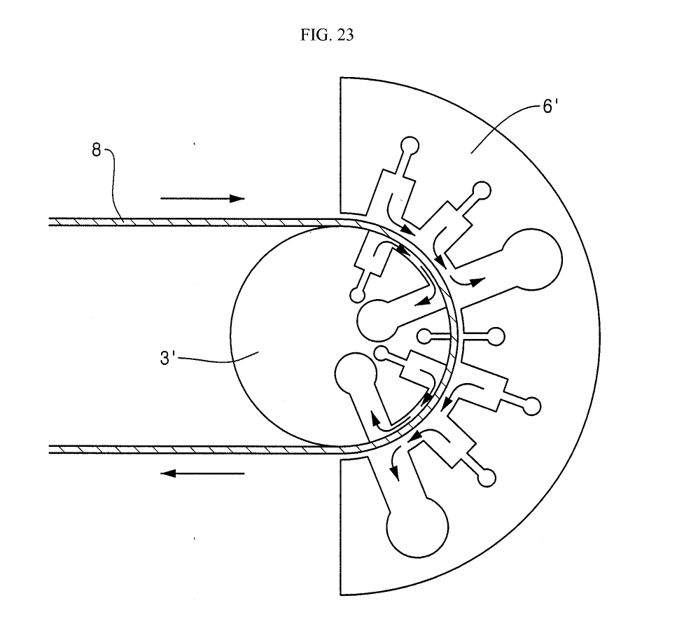

FIG. 23 is a cross-sectional view of a vapor deposition reactor according to still another embodiment. A thin film may be simultaneously formed on the inner surface and exterior wall of a flexible substrate 8 by combining two kinds of vapor deposition reactors according to embodiments. That is, the vapor deposition reactor according to the embodiment may include two bodies 3′ and 6′. One body 3′ may have the shape of a cylinder, and may be moved while the flexible substrate 8 on which the thin film is to be deposited is wound around the body 3′. Meanwhile, the other body 6′ may have the shape of a cylinder with an opening or may have the shape of a portion of the cylinder. The body 3′ is positioned on the inner surface of the body 6′, and the flexible substrate 8 may be moved in a space between the body 3′ and the body 6′. The thin film may be formed simultaneously formed on the inner surface and exterior wall of the flexible substrate 8 using one or more injection portions and exhaust portions formed in each of the bodies 3′ and 6′.

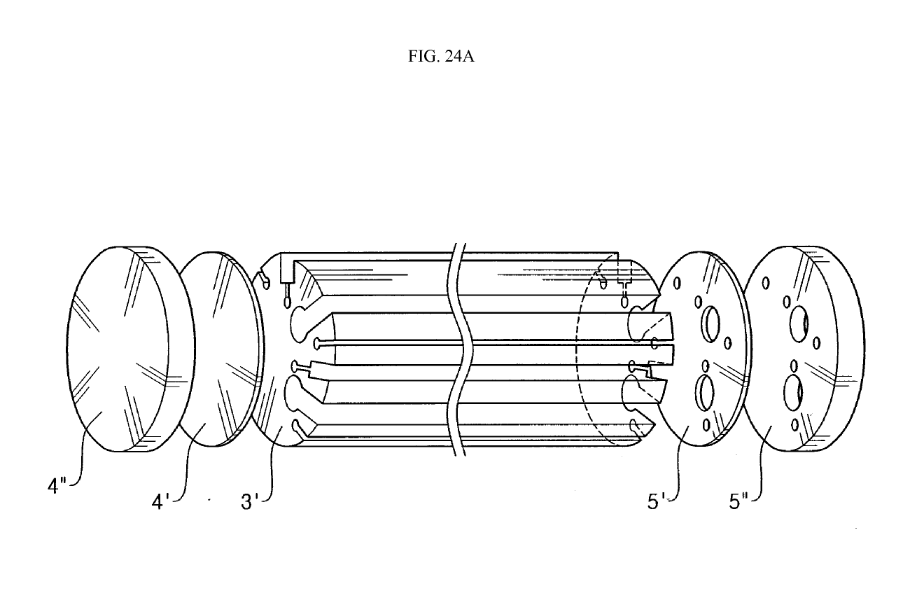

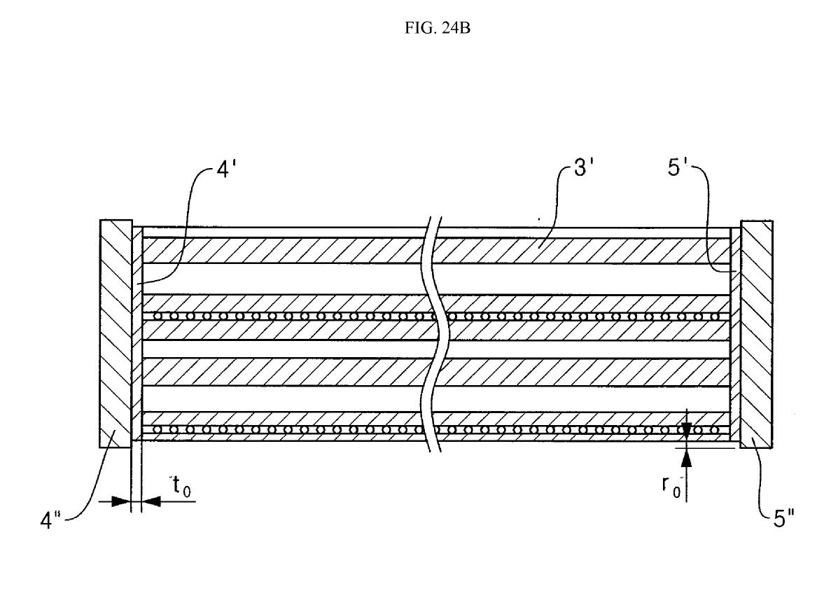

FIG. 24A is an exploded perspective view of a vapor deposition reactor according to an embodiment. FIG. 24B is a longitudinal sectional view of the vapor deposition reactor shown in FIG. 24A. FIGS. 24A and 24B are views a vapor deposition reactor having a body for winding and transporting a flexible substrate as described with reference to FIGS. 21 to 23. The vapor deposition reactor may include an injection portion for injecting a reactant, an injection portion for injecting an inert gas, a body 3′ having an exhaust portion and the like formed therein, and covers 4′ and 5′ positioned to cover both end portions of the body 3′. In this instance, one or more openings for injection or exhaustion of the reactant and inert gas may be formed in the cover 5′ in one direction. The covers 4′ and 5′ may have a thickness t₀ of about 1 to 5 mm.

The vapor deposition reactor may further include edge guides 4″ and 5″ respectively positioned at the outsides of the covers 4′ and 5′ that cover both the end portions of the body 3′. The edge guides 4″ and 5″ may come in contact with a side of a flexible substrate so as to transport the flexible substrate. The edge guides 4″ and ₅″ may be configured to have a greater diameter than the body 3′ of the flexible substrate and the covers 4′ and 5′. For example, the radius of the edge guides 4″ and 5″ may have a difference r₀ of about 0.1 to 3 mm from that of the covers 4′ and 5′. As a result, the flexible substrate transported by the edge guides 4″ and 5″ may be relatively moved with respect to the body 3′ while not coming in contact with the body 3′.

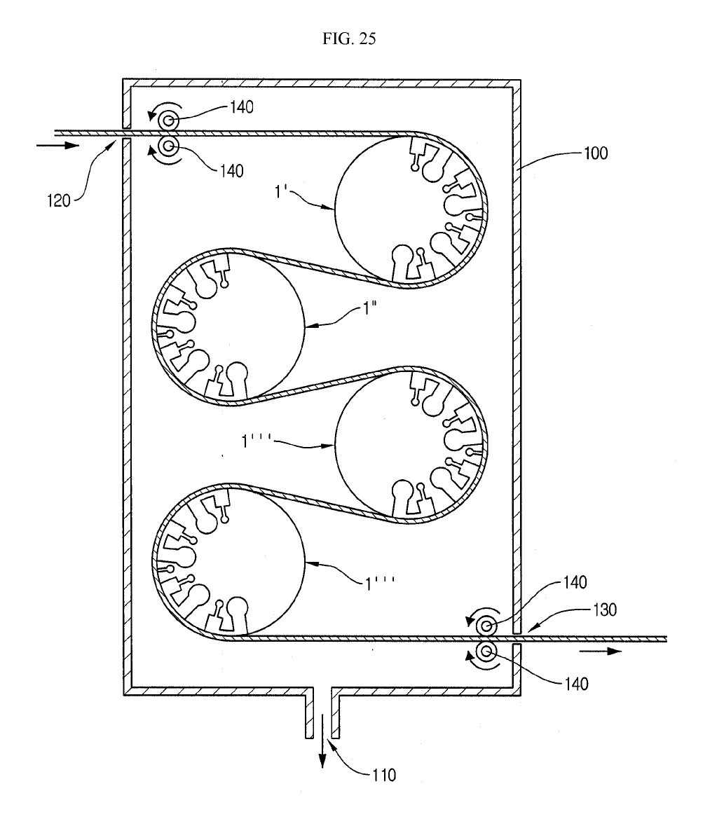

FIG. 25 is a schematic view of a vapor deposition apparatus including a vapor deposition reactor according to an embodiment. The vapor deposition apparatus according to the embodiment may be configured by arranging vapor deposition reactors 1, 1′, 1″ and 1′ in a chamber 100 having an exhaust portion 110, an inlet portion 120 and an outlet portion 130. A flexible substrate 8 is transported by a roller 140 and injected into the chamber 100 through the inlet portion 120. The flexible substrate 8 is transported by being wound by the vapor deposition reactors 1, 1′, 1″ and 1″′ in the chamber 100. In this instance, the first and third vapor deposition reactors 1 and 1″ may allow a thin film to be deposited on a surface of the flexible substrate 8. The second and fourth vapor deposition reactors 1′ and 1′ may allow a thin film to be deposited on another surface of the flexible substrate 8. After the deposition is completed, the flexible substrate 8 may be moved to the exterior of the chamber 100 through the outlet portion 130.

A body of the first to fourth vapor deposition reactor 1, 1′, 1″ and 1″′ may have a diameter of about 100 mm. Each of the first to fourth vapor deposition reactors 1, 1′, 1″ and 1″′ may include two unit modules, and each of the unit modules may be configured to inject TMA as a source precursor and to inject H₂O as a reactant precursor. The TMA and/or H₂O may be injected using an Ar bubbling method of about 10 to 100 sccm. The temperature in the chamber 100 may be about 50 to 250° C., and the pressure in the chamber 100 may be about 50 mTorr to about 1 ATM. The flexible substrate 8 may be a polycarbonate film having a thickness of about 0.5 mm. The transportation speed of the flexible substrate 8 by the roller 140 may be about 100 to 1000 mm per minute.

By using the vapor deposition apparatus configured as described above, Al₂O₃ and ALD films may be respectively formed on both surfaces of the flexible substrate 8 while the flexible substrate 8 passes through the first to fourth vapor deposition reactors 1, 1′, 1″ and 1″′. In this instance, the growth rate of the Al₂O₃ and ALD films is about 0.8 to 1.5 Å while the flexible substrate 8 passes through the unit module. Since each of the vapor deposition reactors 1, 1′, 1″ and 1′ includes two unit modules, the growth rate of the thin films is about 1.6 to 3 Å while the flexible substrate 8 passes through the vapor deposition reactors 1, 1′, 1″ and 1″′.

If a vapor deposition apparatus as shown in FIG. 25 is used, a smaller chamber 100 is used as that of the conventional roll-to-roll deposition system, and therefore, the footprint of the apparatus can be reduced. The number of the vapor deposition reactors 1, 1′, 1″ and 1″′ included in the apparatus and/or the number of the unit modules included in each of the vapor deposition reactors 1, 1′, 1″ and 1″′ are increased, so that the thickness of a thin film formed without increasing the footprint of the apparatus can be increased. Since the deposition is performed on both the surfaces of the flexible substrate 8, stress applied to the flexible substrate 8 can be reduced. Also, since the vapor deposition reactor and the flexible substrate 8 are adhered closely to each other, the chamber 100 having low vacuum degree or ATM pressure can be used.

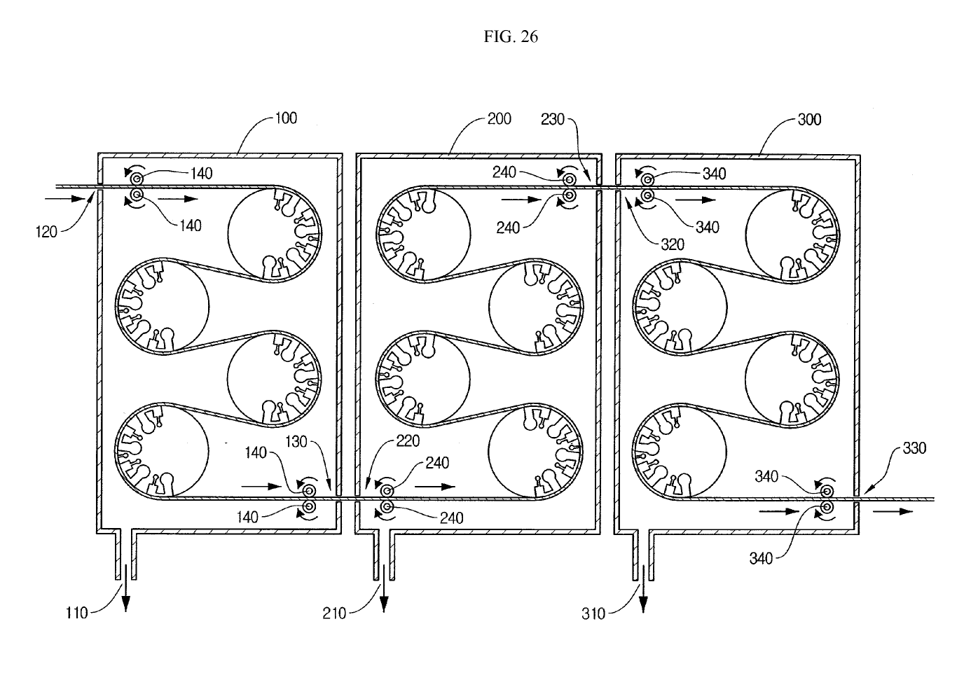

FIG. 26 is a schematic view of a vapor deposition apparatus including a vapor deposition reactor according to another embodiment. The vapor deposition apparatus may include a plurality of chambers 100, 200 and 300 positioned adjacent to one another. A flexible substrate 8 that exiting an outlet portion 130 of the first chamber 100 enters an inlet portion of the second chamber 200. The flexible substrate 8 that comes out of an outlet portion 230 of the second chamber 200 enters an inlet portion 320 of the third chamber 300. In one or more vapor deposition reactors positioned in the first and third chambers 100 and 300, TMA may be injected as a source precursor, and H₂O may be injected as a reactant precursor. On the other hand, in one or more vapor deposition reactors positioned in the second chamber 200, TEMATi may be injected as a source precursor, and H₂O may be injected as a reactant precursor.

As a result, an Al₂O₃ layer may be formed on both the surfaces of the flexible substrate 8 while the flexible substrate 8 passes through the first and third chambers 100 and 300. On the other hand, a TiO₂ layer may be formed on both the surfaces of the flexible substrate 8 while the flexible substrate 8 passes through the second chamber 200. That is, a nano-laminate film configured as Al₂O₃/TiO₂/Al₂O₃ may be formed while the flexible substrate 8 passes through the entire vapor deposition apparatus. The growth rate of the Al₂O₃ layer may be about 0.8 to 2.5 Å while the flexible substrate 8 passes through each of the unit modules of the vapor deposition reactor. The growth rate of the Al₂O₃ layer may be about 1.6 to 5.0 Å while the flexible substrate 8 passes through each of the vapor deposition reactors. Meanwhile, the growth rate of the TiO₂ layer may be about 1 to 5 Å while the flexible substrate 8 passes through each of the unit modules of the vapor deposition reactor. The growth rate of the Al₂O₃ layer may be about 2 to 10 Å while the flexible substrate 8 passes through each of the vapor deposition reactors.

In another embodiment, an Alq₃ (tris(8-hydroxyquinolinato)aluminum) layer may be formed using the vapor deposition reactor according to the aforementioned embodiments. The Alq₃ layer may be a layer used in an organic light-emitting diode (OLED) display device or the like. In a case where the Alq₃ layer is desired to be formed, the chamber of the vapor deposition apparatus may be heated at about 100 to 350° C. For example, the temperature of the chamber may be about 250° C. Since the wall of the chamber is heated, it is possible to prevent molecule condensation. The reactive molecules to be deposited in a vapor phase are carried through the chamber on a carrier gas (e.g., argon) via a liquid delivery system (LDS) or a sublimer. The base pressure of the chamber may be about 10 to 4 Torr, and the working pressure of the chamber may be about 10 mTorr to about 1 Torr.

The process of forming the Alq₃ layer using the vapor deposition reactor according to the embodiment is as follows. First a seed molecule layer ma_{y} be formed by injecting TMA on the surface of a substrate to be deposited. The injection time of the TMA may be adjusted to be about 10 to 50 msec by controlling parameters of the vapor deposition reactor and/or the relative movement speed of the substrate and the vapor deposition reactor. As a result, (CH₃)₂—Al— may be covalently bonded on the surface of the substrate.

Subsequently, after the seed molecule layer is formed, 8-hydroxyquinoline (C₉H₇NO) may be injected onto the substrate. The injection time of the 8-Hydroxyquinoline may be adjusted to be about 20 to 100 msec. Two molecules of 8-Hydroxyquinoline replace (CH₃) legand of a seed molecule, and form Al(C₉H₆NO)₂ on the surface of the substrate. As a result, the surface of the substrate is covered with (C₉H₆NO). The surface becomes very intimate with Alq₃ because of the same legand with Alq₃. Extra 8-Hydroxyquinoline molecules may be removed by a skimming process using an inert gas.

Subsequently, Alq₃ molecules for forming an organic layer may be injected onto the surface of the substrate. The Alq₃ molecules may be injected in a gas phase state. The injection process of the Alq₃ molecules may be repeatedly performed until the layer having a desired thickness can be obtained. Subsequently, a process of post-treating the formed organic layer into plasma is performed. In this instance, remote plasma generated from NH₃ or the like may be used to form an amine group as a reactive group on the surface of the substrate. For example, the substrate may be exposed to NH₃ remote plasma for about 10 msec to 1 second.

Subsequently, TMA may be injected onto the surface of the organic layer formed on the substrate. For example, the injection time of the TMA may be adjusted to be about 10 to 50 msec. The processes described above may be repeatedly performed as needed so as to obtain one or more Alq₃ layers. The processes and parameters described related to the formation of the Alq₃ layer are provided herein merely for illustrative purposes. That is, the forming process of the Alq₃ layer may be performed through a modified embodiment which is not described in this specification.

The process has been illustratively described herein describing a thin film formed on a curved surface of an interior wall of a tube, an exterior wall of a tube, a front-side of a flexible substrate, a back-side of a flexible substrate, or both sides of a flexible substrate, using the vapor deposition reactor according to the embodiments. However, the surface on which the deposition can be performed using a vapor deposition reactor and a method for forming a thin film according to the embodiments is not limited to those described in this specification, and the embodiments may be applied to allow a thin film on an non-planar surface.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A vapor deposition reactor comprising:
a first portion formed with a first recess at a first location of a circular arc, the first recess communicatively connected to at least one first injection portion for injecting a first material into the first recess;
a second portion at a second location of the circular arc adjacent to the first portion, the second portion formed with a second recess communicatively connected to the first recess; and
a third portion at a third location of the circular arc adjacent to the second portion, the third portion formed with a third recess communicatively connected to the second recess and an exhaust portion for discharging the first material from the vapor deposition reactor.

2. The vapor deposition reactor according to claim 1, further comprising a fourth portion at a fourth location of the circular arc, the fourth portion connected to at least one second injection portion for injecting an inert gas, the exhaust portion further discharging the inert gas from the vapor deposition reactor.

3. The vapor deposition reactor according to claim 2, wherein the inert gas comprises one or more gas selected from the group consisting of N₂, Ar and He.

4. The vapor deposition reactor according to claim 1, further comprising a body at least partially having the shape of a cylinder, wherein the first to third portions are formed on a surface of the body and are arranged along a circumference of the body.

5. The vapor deposition reactor according to claim 4, wherein the vapor deposition reactor is configured to rotate with a substrate having a curved surface mounted on the vapor deposition reactor.

6. The vapor deposition reactor according to claim 1, further comprising a body at least partially having the shape of a cylinder with a through-hole, wherein the first to third portions are formed on a surface of the through-hole.

7. The vapor deposition reactor according to claim 1, wherein the first material comprises one or more selected from the group consisting of a source precursor, reactant precursor, inert gas, reactant gas or mixture thereof.

8. The vapor deposition reactor according to claim 1, wherein the first recess, the second recess and the third recess are connected in sequence.

9. The vapor deposition reactor according to claim 1, wherein a cavity is communicatively connected to the at least one first injection portion; and the vapor deposition reactor comprising a plurality of electrodes for generating a radical of the first material by applying voltage to the first material in the cavity.

10. The vapor deposition reactor according to claim 1, further comprising:
a fifth portion at a fifth location of the circular arc adjacent to the first portion, the fifth portion formed with a fifth recess communicatively connected to the first recess; and
a sixth portion at a six location of the circular arc adjacent to the fifth portion, the sixth portion formed with a sixth recess communicatively connected to the fifth recess and at least one third injection portion for injecting a second material into the sixth recess.

11. The vapor deposition reactor according to claim 10, wherein the second material comprises one or more gas selected from the group consisting of a source precursor, reactant precursor, inert gas, reactant gas or mixture thereof.

12. The vapor deposition reactor according to claim 10, wherein the sixth recess, the fifth recess, the first recess, the second recess and the third recess are connected in sequence.

13. The vapor deposition reactor according to claim 10, wherein a cavity is communicatively connected to the at least one third injection portion; and the vapor deposition reactor comprises a plurality of electrodes for generating a radical of the second material by applying voltage to the second material in the cavity.

14. The vapor deposition reactor according to claim 1, further comprises:
a fifth portion at a fifth location of the circular arc adjacent to the third portion, the fifth portion formed with a fifth recess communicatively connected to the third recess; and
a sixth portion at a sixth location of the circular arc adjacent to the fifth portion, the sixth portion formed with a sixth recess communicatively connected to the fifth recess and at least one third injection portion for injecting a second material into the sixth recess.

15. The vapor deposition reactor according to claim 14, wherein the second material comprises one or more gas selected from the group consisting of a source precursor, reactant precursor, inert gas, reactant gas or mixture thereof.

16. The vapor deposition reactor according to claim 14, wherein the first recess, the second recess, the third recess, the fifth recess and the sixth recess are connected in sequence.

17. The vapor deposition reactor according to claim 14, wherein a cavity is communicatively connected to the at least one third injection portion; and the vapor deposition reactor comprises a plurality of electrodes for generating a radical of the second material by applying voltage to the second material in the cavity.

18. A method for forming a thin film on a curved surface, comprising:
providing a vapor deposition reactor comprising a first portion, a second portion and a third portion arranged along an arc of a circle;
filling a first material in a first recess formed in the first portion by providing the first material via at least one first injection portion;
receiving the first material in a second recess formed in the second portion via the first recess, the second portion located adjacent to the first portion;
receiving the first material in a third recess formed in the third portion via the second recess, the third portion located adjacent to the second portion;
discharging the first material in the third recess via an exhaust portion formed in the third portion; and
moving the curved surface across the first recess, the second recess and the third recess.

19. The method according to claim 18, further comprising:
injecting an inert gas between the vapor deposition reactor and the curved surface; and
discharging the inert gas via the exhaust portion.

20. The method according to claim 19, wherein the inert gas comprises one or more selected from the group consisting of N₂, Ar and He.

21. The method according to claim 18, wherein the first material comprises one or more gas selected from the group consisting of a source precursor, reactant precursor, inert gas, reactant gas or mixture thereof.

22. The method according to claim 18, further comprising applying voltage to a plurality of electrodes in a cavity communicatively connected to the at least one first injection portion to generate a radical of the first material.

23. The method according to claim 18, wherein the vapor deposition reactor further comprises a fifth portion and a sixth portion arranged along the arc of the circle, the method further comprising:
filling a second material in a sixth recess formed in the sixth portion by providing the second material via at least one third injection portion;
receiving the second material in a fifth recess formed in the fifth portion via the sixth recess, the fifth portion located adjacent to the sixth portion and the first portion;
receiving the second material in the first recess via the fifth recess;
receiving the second material in the second recess via the first recess;
receiving the second material in the third recess via the second recess; and
discharging the second material in the third recess via the exhaust portion.

24. The method according to claim 23, wherein the second material comprises one or more gas selected from the group consisting of a source precursor, reactant precursor, inert gas, reactant gas or mixture thereof.

25. The method according to claim 23, further comprising applying voltage to a plurality of electrodes in a cavity communicatively connected to the at least one third injection portion to generate a radical of the second material.

26. The method according to claim 18, wherein the vapor deposition reactor further comprises a fifth portion and a sixth portion arranged along the arc of the circle, the method further comprising:
filling a second material in a sixth recess formed in the sixth portion by providing the second material via at least one third injection portion;
receiving the second material in a fifth recess formed in the fifth portion via the sixth recess, the fifth portion located adjacent to the sixth portion and the third portion;
receiving the second material in the third recess via the second recess; and
discharging the second material in the third recess via the exhaust portion.

27. The method according to claim 26, wherein the second material comprises one or more selected from the group consisting of a source precursor, reactant precursor, inert gas, reactant gas or mixture thereof.

28. The method according to claim 26, further comprising applying voltage to a plurality of electrodes in a cavity communicatively connected to the at least one third injection portion to generate a radical of the second material.
